(19) United States
(12) Patent Application Publication
(10) Pub. No.: US 2009/0140271 A1
(43) Pub. Date: Jun. 4, 2009

(54) LIGHT EMITTING UNIT

(76) Inventor: Wen-Jyh Sah, Tainan City (TW)

Correspondence Address: BIRCH STEWART KOLASCH & BIRCH, PO BOX 747, FALLS CHURCH, VA, 22040-0747, US

(21) Appl. No.: 12/323,227

(22) Filed: Nov. 25, 2008

(30) Foreign Application Priority Data
Nov. 30, 2007 (TW) 096145786
Nov. 30, 2007 (TW) 096145787
Nov. 30, 2007 (TW) 096145788
Aug. 20, 2008 (TW) 097131771

(51) Int. Cl. H01L 33/00

(52) U.S. Cl. 257/88; 257/E33.061

(57) ABSTRACT

A light emitting unit has a chamber. The light emitting unit includes at least one substrate, a plurality of light emitting diode (LED) dies and a gel or a fluid. The LED dies are disposed on the substrate and in the chamber. At least two LED dies are electrically connected to each other in series or in parallel. The gel or the fluid is filled in the chamber.

### CROSS REFERENCE TO RELATED APPLICATIONS

This Non-provisional application claims priority under 35 U.S.C. §119(a) on Patent Application No(s). 096145786, 096145787 and 096145788 filed in Taiwan, Republic of China on Nov. 30, 2007, and Patent Application No(s). 097131771 filed in Taiwan, Republic of China on Aug. 20, 2008, the entire contents of which are hereby incorporated by reference.

### BACKGROUND OF THE INVENTION

1. Field of Invention

The present invention relates to a light emitting unit and, in particular, to a light emitting unit having a chamber.

2. Related Art

Because the light emitting diode (LED) has the advantages of high light intensity and energy saving, as the LED technology is getting matured, it can be applied to more fields such as the light source and the backlight source.

FIG. 1 is a schematic view of a conventional light emitting unit 1. With reference to FIG. 1, the conventional light emitting unit 1 includes a substrate 11, a plurality of LED dies 12, a molding compound 13 and a lamp house 14. The LED die 12 is disposed and electrically connected to the substrate 11 by wire-bonding. The molding compound 13 is made of a transparent material and protects the LED die 12 by sealing. The lamp house 14 is used to reflect and concentrate the light emitting direction of the LED die 12.

In prior art, when the LED die 12 emits the light, a large amount of heat energy will be produced. Because the materials of the LED die 12, cured molding compound 13, substrate 11 and lamp house 14 have different heat expansion rates, the wire W disposed between them will be deformed or broken by squeezing and dragging, such that the LED die 12 may not be able to emit the light and the light emitting unit 1 can be damaged. The heat expansion effect could be more severe for the light emitting unit 1 with a large area of molding compound.

Additionally, the conventional structure cannot solve the heat dissipation problem of the LED die 12. The PN junction with the highest temperature is still covered within the molding compound 13 with high thickness, and thus the heat can only be guided to the substrate 11 by thermal conduction.

Therefore, it is an important subject to provide a light emitting unit that the breaking caused by different heat expansion rates of the housing, molding compound, LED die and substrate can be prevented and the heat dissipation problem can be solved.

### SUMMARY OF THE INVENTION

In view of the foregoing, the present invention is to provide a light emitting unit that can enhance the heat dissipation effect of a light emitting diode (LED) die.

In view of the foregoing, the present invention is to provide a light emitting unit that can prevent a wire of an LED die from breaking for different heat expansion rates of a housing, a molding compound, the LED die, and a substrate.

To achieve the above, a light emitting unit according to the present invention has a chamber. The light emitting unit includes a substrate, a plurality of LED dies, and a gel or a fluid. The LED dies are disposed on the substrate and located in the chamber. The gel and the fluid are filled in the chamber.

As mentioned above, since the light emitting unit of the present invention allows the LED die to dispose in a chamber, the light emitting unit no longer needs a molding compound with a large area and high thickness to entirely cover the LED dies. Without separation from the molding compound, the heat can be dissipated from the substrate below the LED die and also from the top of the LED die. Meanwhile, the heat dissipation effect can be enhanced by the heat convection effect of the gel or the fluid, and the deformation or the breaking of the wire connected between the LED die and the substrate caused by dragging and squeezing can be avoided. In addition, the LED die can be protected from the moisture, dust, or other environmental factors by the housing. Moreover, the light emitting unit of the present invention still can use the molding compound, which partially covers a single LED die, for enhancing the light extraction efficiency and the light emission range of the LED die.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic view of a conventional light emitting unit;

FIGS. 2A to 2C are schematic views of a light emitting unit according to a first embodiment of the present invention, in which FIG. 2C is a cross-sectional view of FIG. 2B along a line A-A;

FIGS. 2D and 2E are schematic views of the light emitting unit in other various aspects according to the first embodiment of the present invention;

FIGS. 2F and 2G are cross-sectional views of FIG. 2E in other various aspects along a line E-E;

FIGS. 3A and 3B are schematic views of a light emitting unit according to a second embodiment of the present invention, in which FIG. 3B is a cross-sectional view of FIG. 3A along a line C-C;

FIGS. 3C and 3D are schematic views of the light emitting unit in other various aspects according to the second embodiment of the present invention;

FIGS. 3E and 3F are schematic views of the light emitting unit in yet other various aspects according to the second embodiment of the present invention;

FIGS. 4A and 4B are schematic views of a light emitting unit according to a third embodiment of the present invention, in which FIG. 4B is a cross-sectional view of FIG. 4A along a line D-D;

FIG. 4C is a schematic view of the light emitting unit in another various aspect according to the third embodiment of the present invention;

FIGS. 4D, 4E, and 4F are schematic views of the light emitting unit in yet other various aspects according to the third embodiment of the present invention;

FIG. 5A is a schematic view of a light emitting unit according to a fourth embodiment of the present invention;

FIG. 5B is a schematic view of the light emitting unit in another various aspect according to the fourth embodiment of the present invention;

FIG. 5C is a schematic view of the light emitting unit in yet another various aspect according to the fourth embodiment of the present invention;

FIG. 6A is a schematic view of a light emitting unit according to a fifth embodiment of the present invention;

FIG. 6B is schematic view of the light emitting unit in another various aspect according to the fifth embodiment of the present invention;

FIGS. 6C to 6G are schematic views of a light emitting unit in different various aspects according to a sixth embodiment of the present invention, in which FIGS. 6D to 6G are different cross-sectional views of FIG. 6C along a line E-E;

FIGS. 7A to 7D are schematic views in different aspects of a long axis of a substrate in the light emitting unit according to the sixth embodiment of the present invention;

FIG. 7E is a schematic view of the light emitting unit in another various aspect according to the sixth embodiment of the present invention;

FIGS. 8A and 8B are schematic views of a light emitting unit according to a seventh embodiment of the present invention, in which FIG. 8B is a schematic assembled view of FIG. 8A;

FIG. 8C is a schematic view in another aspect of the light emitting unit in FIG. 8B along a line F-F;

FIGS. 8D and 8E are schematic views of the light emitting unit in yet another aspect according to the seventh embodiment of the present invention;

FIGS. 9A to 9K are schematic views of a light emitting unit in different aspects according to an eighth embodiment of the present invention, in which FIG. 9B is a cross-sectional view of FIG. 9A along a line G-G; and

FIGS. 10A to 10E are schematic views of the light emitting unit in different aspects according to the eighth embodiment of the present invention.

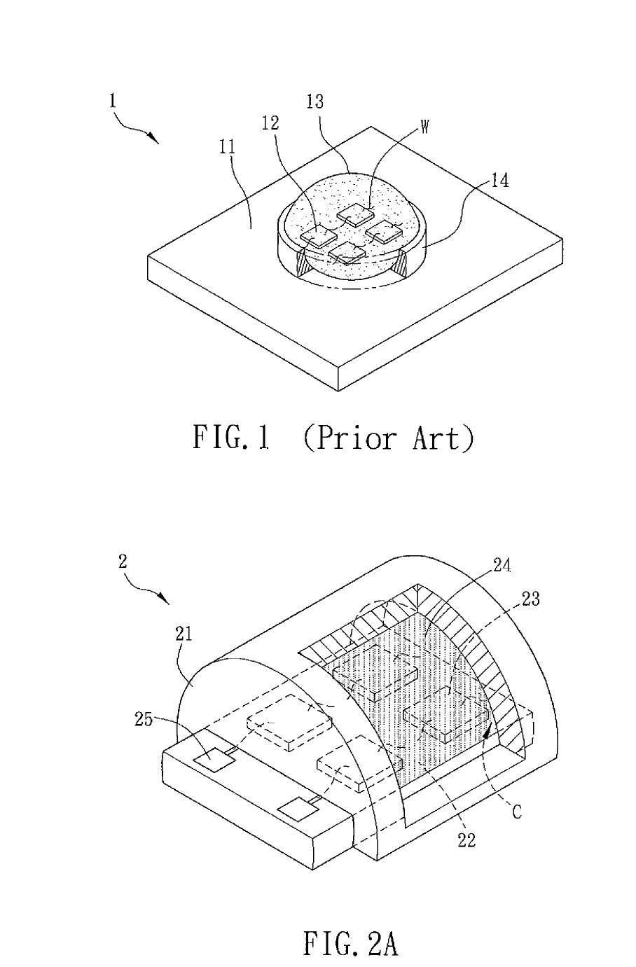

### DETAILED DESCRIPTION OF THE INVENTION

The present invention will be apparent from the following detailed description, which proceeds with reference to the accompanying drawings, wherein the same references relate to the same elements.

A light emitting unit has a chamber and includes a substrate, a plurality of light emitting diode (LED) dies, and a gel or a fluid. The light emitting unit may be an illuminant unit, an indication unit, an advertising panel, a backlight source of a liquid crystal display (LCD) device, or a light source of an electronic device. The light emitting unit according to various embodiments of the present invention will be detailed described as follows.

### First Embodiment

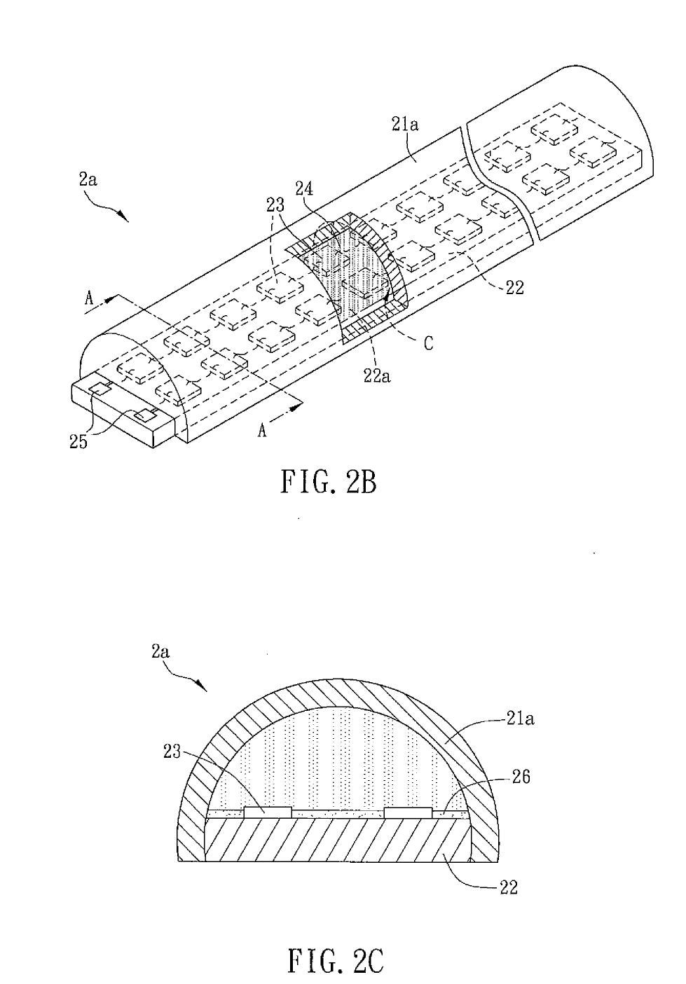

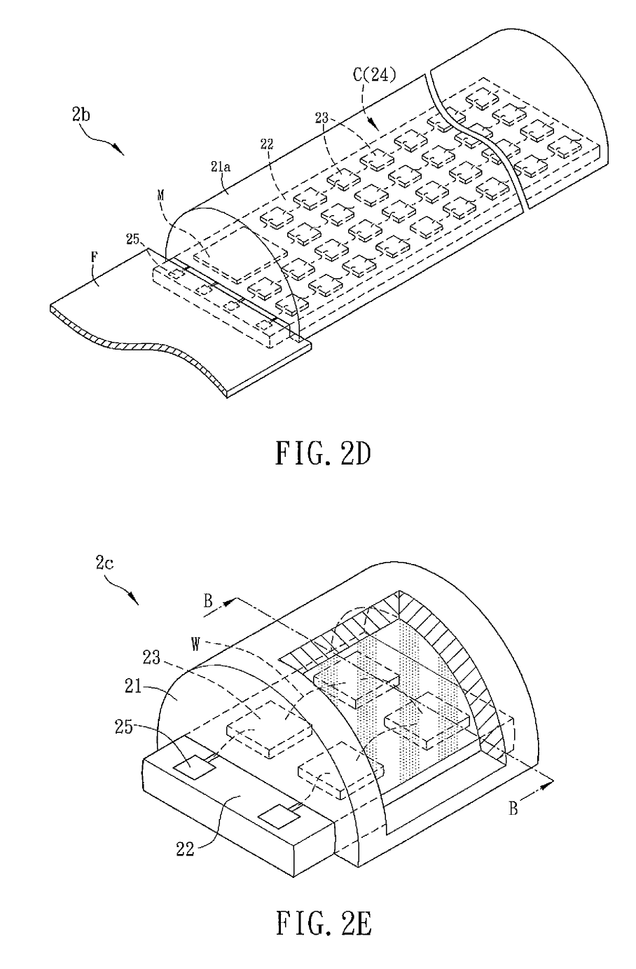

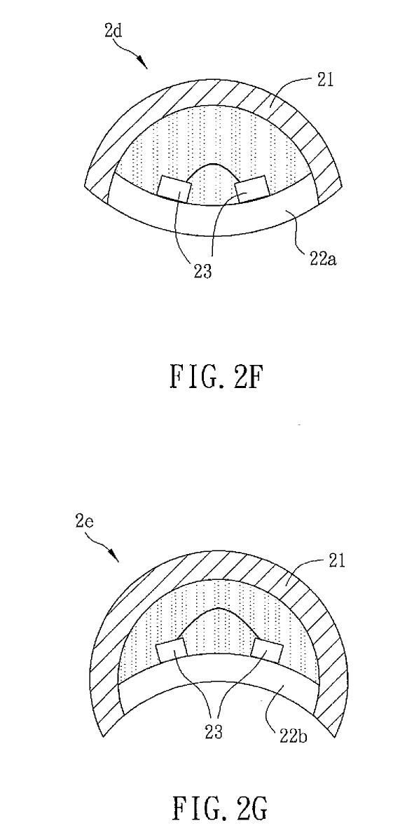

FIGS. 2A to 2C are schematic views of a light emitting unit according to the embodiment. As shown in FIG. 2A, the light emitting unit 2 includes a housing 21, a substrate 22, a plurality of LED dies 23, and a gel or a fluid 24. In the embodiment, the housing 21 and the substrate 22 form a chamber C for example.

In the embodiment, the housing 21 is an arc-shape housing for example, and the housing 21 may also be a hemispheric housing. The housing 21 may include a transparent part and a non-transparent part, i.e. the housing 21 may be partially transparent (thus the housing 21 can be called a transparent housing) and partially non-transparent. As a matter of course, the housing 21 may also be entirely transparent. The material of the transparent part is, for example, at least one of polymer, glass, and quartz. The material of the non-transparent part is, for example, at least one of polymer, ceramics, and metal. It is noted that for easily identifying the element, an arc-shape opening is cut on the housing 21 in FIG. 2A; however, the arc-shape opening is not the essential technical feature of the present invention. In the embodiment, the material of the housing 21 is transparent polymer for example, which is at least one of polystyrene (PS), polycarbonate (PC), methylstyrene (MS), polymethylmethacrylate (PMMA), and acrylonitrile butadiene styrene (ABS).

A plurality of scattering centers may also be doped in the housing 21 made of transparent polymer for enhancing the light diffusion effect. The scattering center is a scattering particle or a scattering bubble for example. The material of the scattering particle may be an organic scattering particle or an inorganic scattering particle, e.g. BaSO4, SiO2, or Al2O3, having different refractive index than the housing 21.

The material of the substrate 22 includes glass, resin, ceramics, alloy, metal, or their combination. The substrate 22 may be simply a metal substrate or may have a circuit layer to form a circuit substrate, for example, a glass circuit board, a printed circuit board (PCB), a ceramic circuit board, or a metal core PCB. The substrate 22 is a PCB for example and forms the chamber C with the housing 21. In the embodiment, the chamber C is, for example but not limited to, an airtight space. The chamber C may also be a non-airtight space, e.g. the housing 21 may have an opening, such that the air inside and outside the chamber C can form the heat convection. Alternatively, the housing 21 and the circuit substrate 22 are merely connected and fixed to each other and still leave some gap in between, thus the chamber C does not form the air tight space.

The LED dies 23 may be arranged one-dimensionally, two-dimensionally, or in array, and disposed on the substrate 22. The LED die 23 can be electrically connected to the substrate 22 by flip-chip or wire-bonding. At least two of the LED dies 23 are electrically connected in series or in parallel. In the embodiment, the LED dies 23 are arranged two-dimensionally and disposed to the substrate 22 by wire-bonding.

The emission spectrum of the LED die 23 is in a visible light range and/or an ultraviolet (UV) range for example. If the emission spectrum of the LED die 23 is in the visible light range, the LED dies 23 can be red light LED dies, green light LED dies, blue light LED dies, or their combination, which means, the LED dies 23 are able to emit the light in the same or different colors.

The gel or the fluid 24 is filled in the chamber C. The gel may be a melted gel, a liquid gel, a semi-cured gel, an elastic gel, or a cured gel for example. The fluid 24 may be gas or liquid. For example, the gas may be air or inert gas and the liquid may be oil or solvent. In the embodiment, the chamber C is filled up with the fluid 24 for example but not limited to this. Moreover, by selecting a gel or the fluid 24 with a specified refractive index, the refractive index of the gel or the fluid 24 is between that of the LED die 23 and of the air (e.g. the refractive index of the gel or the fluid 24 may be larger than 1.3), such that the light extraction efficiency of the LED die 23 can be increased. It is noted that when the gel or the fluid 24 is filled in the chamber C, it may or may not be completely filled up. For example, the gel or the fluid 24 may be filled to just above the light emitting surfaces of the LED dies 23. In addition, since the shape of the housing 21 in the embodiment is an arc shape, the surface of housing 21 that the gel or the fluid 24 contacts to is a curved surface, so that the refractive index of the gel or the fluid 24 can be selected to be larger than or equal to that of the material of the housing 21, such that the light emitting surface of the housing 21 has an effect similar to a convex lens for concentrating the light emitted from the LED die 23.

Because the LED dies 23 are located in the chamber 211 of the housing 21, the light emitting unit 2 of the present invention does not need the molding compound with a large area and high thickness for covering the LED dies 23. Without separation of the molding compound, the heat is dissipated not only from the substrate 22 below the LED die 23 but also from the top of the LED die 23, and the heat dissipation effect of the LED dies 23 is enhanced by heat convection effect of the gel or the fluid 24. Furthermore, the housing 21 can protect the LED die 23 from the environmental factor such as moisture or dust and prevent the wire connected between the LED die 23 and the substrate 22 from deforming and breaking by dragging and squeezing.

In the embodiment, the light emitting unit 2 may further include at least two connecting electrodes 25 that are electrically connected to the LED dies 23. The connecting electrodes 25 can be disposed on an end of the substrate 22 or respectively two ends of the substrate 22. In the embodiment, the connecting electrodes 25 are disposed on an end of the substrate 22 for example, and located outside of the housing 21. The connecting electrode 25 may be an electrical connecting pad or a connector.

FIG. 2C is a cross-sectional view of FIG. 2B along a line A-A. With reference to FIGS. 2B and 2C, the long strip type substrate 22a and the housing 21a are used in the light emitting unit 2a, so that more of the LED dies 23 can be disposed on the substrate 22a for increasing the applications. Moreover, the light emitting unit 2a may further include a reflecting layer 26 that is disposed on the peripheries of the LED dies 23. The light emitted from the LED die 23 to the substrate 22 is reflected by the reflecting layer 26, such that the utilization rate of the light emitted from the LED die 23 can be increased. If the substrate 22 is a transparent substrate, the reflecting layer 26 can be disposed on another surface of the substrate 22, so that the LED die 23 and the reflecting layer 26 are disposed on opposite sides of the substrate 22. The material of the reflecting layer 26 can be metal, metal oxide, or white coating, e.g. Al2O3, TiO2, or BaSO4. The reflective spectrum is at least one of an UV waveband (200 to 400 nm), a visible blue light waveband (400 to 480 nm), or a full visible light waveband (400 to 780 nm); and the reflectivity is greater than 50%. In addition, the reflecting layer 26 can be disposed to the substrate 22 by coating, printing, or plating. When the substrate 22 is made of polymer, the material of the reflecting layer 26 can be added to the plastic material and then the reflecting layer 26 is formed by pressing or injecting. It is noted that the reflecting layer 26 may use a reflecting film or a multilayer plating material for reflecting the light.

FIG. 2D is another aspect of the light emitting unit 2a in FIG. 2B. As shown in FIG. 2D, the light emitting unit 2b can further include a flexible circuit board F connected to an end of the substrate 22, for example, the flexible circuit board F is electrically connected to the connecting electrode 25 and exposed from the chamber C. The flexible circuit board F may have a control circuit electrically connected to the LED dies 23 through the connecting electrode 25. As a matter of course, the control circuit does not need to be disposed on the flexible circuit board F, which can be used to connect another light emitting unit 2b. A control chip M that is a die or a packing element can be disposed on the substrate 22 by wire-bonding, flip-chip, or surface mount, and is electrically connected to the LED dies 23 for controlling the LED die 23 to emit light. It is noted that the control chip M is disposed in the corner of the substrate 22 and does not interfere the light emission of the LED dies 23. It is also helpful for heat dissipation of the control chip M by having the control chip M covered with the gel or the fluid 24.

Additionally, FIG. 2E is yet another aspect of the light emitting unit 2 in the embodiment. At least two of the LED dies 23 of the light emitting unit 2c are electrically connected to each other in series or in parallel by die-to-die wire-bonding. The electrodes of the LED dies 23 are on the same side of the dies, and the electrical connection is formed between the two LED dies 23 by directly wire-bonding the electrodes through the wire (e.g. the gold wire). About this, the N electrode of the first die is connected to the P electrode of the second die; the N electrode of the second die is connected to the P electrode of the third die; the N electrode of the third die is connected to the P electrode of the fourth die, all through the wire W, and so forth to electrically connect the LED dies 23 in series.

Therefore, the substrate 22 does not need a circuit layer disposed thereon; it can be electrically connected to the connecting electrode 25, which is outside the chamber, by the LED die 23 close to the end of the housing 21, and electrically connected to a control circuit through the connecting electrode 25. Thus, all of the LED dies 23 can be controlled. The connecting electrode 25 may be a part of the substrate 22 or an additional element attached to the substrate 22.

Since there is no circuit layer on the substrate 22, the substrate 22 can be a metal substrate for effectively enhancing the heat dissipation effect of the light emitting unit 2c. Additionally, if the substrate 22 is a transparent substrate without the covering of the circuit layer, the probability that the light emitted from the back of the LED die 23 is reflected in the substrate 22 and then emitted out is effectively increased, so as to increase the light utilization rate of the LED die 23. Furthermore, since the circuit layer is not needed on the substrate 22, the material cost can be reduced and the manufacturing rate can be increased. By decreasing about half of the amount of the wiring material for the LED dies 23, the overall material cost can further be reduced.

FIGS. 2F and 2G are schematic views of FIG. 2E in various aspects along a line B-B. Because there is no circuit layer on the substrates 22a and 22b, they can be bended and manufactured after the disposition of the LED dies 23 is done by die-to-die wiring, so that the concave surfaces of the substrates 22a and 22b face the LED die 23 (as shown in FIG. 2F), or back face the LED die 23 (as shown in FIG. 2G). Of course, even if there is circuit layer on the substrates 22a and 22b, as long as the thicknesses of the substrates 22a and 22b are smaller, their flexibility gets better (e.g. the material such as glass, metal, ceramics, quartz, or polymer); thus the bending can be performed. With flexibility, the substrates 22a and 22b allow the light emitting units 2d and 2e to attach to the surfaces of more objects, so as to increase the applications of the light emitting units 2d and 2e. It is worth to be mentioned that other than bending the substrates 22a and 22b to form the curved surfaces, they can be other shapes according different requirements.

### Second Embodiment

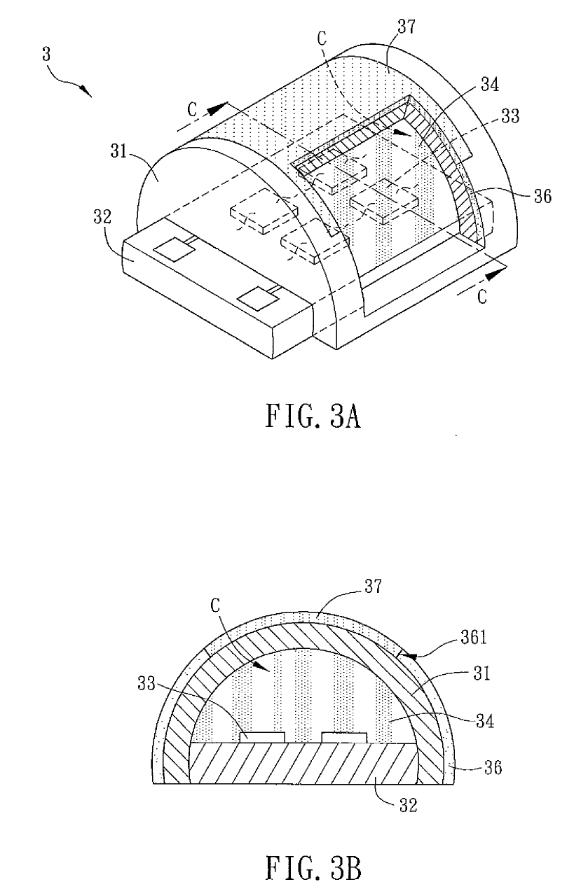

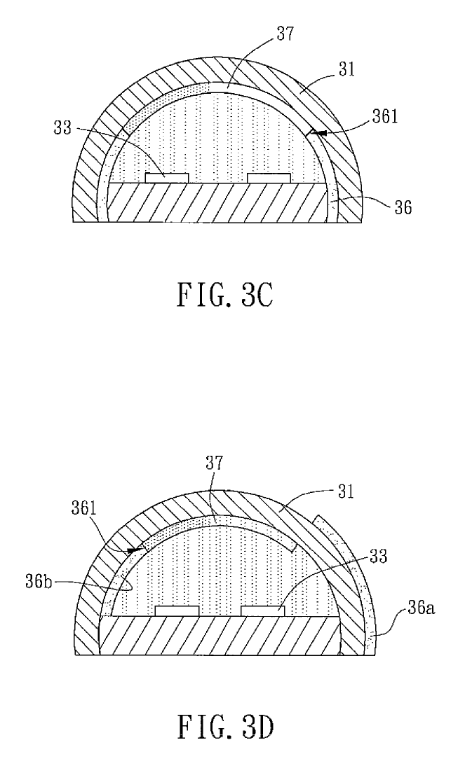

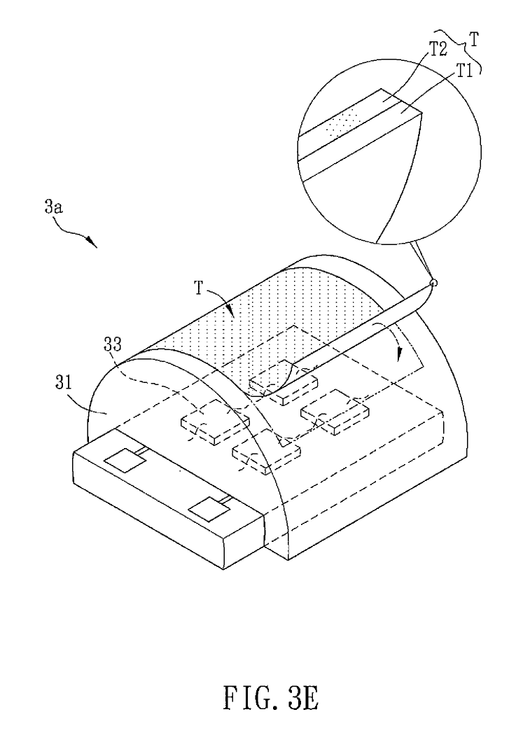

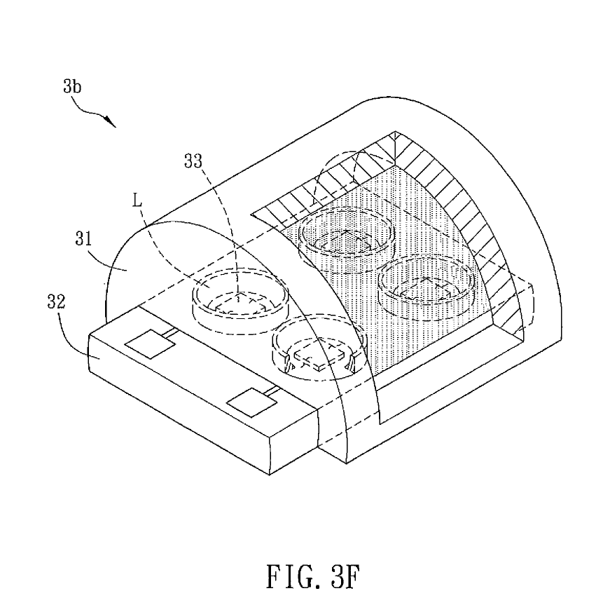

FIGS. 3A and 3B are schematic views of a light emitting unit according to the second embodiment of the present invention, in which FIG. 3B is a cross-sectional view of FIG. 3A along a line C-C. With reference to FIGS. 3A and 3B, the difference between the light emitting unit 3 of the second embodiment and the light emitting 2 of the first embodiment is that the reflecting layer 36 is disposed on the outer surface of the housing 31, and the light emitting unit 3 further includes a wavelength converting material 37 that can be disposed on the partial outer surface and/or the partial inner surface of at least a part of the housing 31, and/or doped in the housing 31.

The reflecting layer 36 also includes an opening 361 corresponding to a light emitting surface of the LED dies 33. In the embodiment, the wavelength converting material 37 is disposed corresponding to the outer surface of the housing 31 and located at the opening 361 of the reflecting layer 36. The wavelength converting material 37 may be a fluorescent material, a phosphorescent material, or other materials that can be excited by the light and generate variation in wavelength. The wavelength converting material 37 is a yellow fluorescent material, a red fluorescent material, a green fluorescent material, a blue fluorescent material, or their combination. It is to be noted that the reflecting layer 36 may be a part of the housing 31 that has a reflecting part, i.e. a non-transparent part, formed while manufacturing, which means, an additional reflecting layer is not needed.

The light emitting direction of the LED die 33 can be concentrated by disposing the reflecting layer 36, and the light emitted from the LED dies 33 is mixed in the housing 37 and then emitted out, such that the light emitting unit 3 can emit a uniform light. Additionally, after the wavelength converting material 37 is excited by the light from the LED die 33, the color of the light emitted from the light emitting unit 3 can be changed to, for example, white. Furthermore, the gel or the fluid 34 filled in the chamber C may also be used to enhance the heat dissipation effect of the LED dies 33.

In addition, FIGS. 3C and 3D are schematic views of the light emitting unit in another various aspect according to the second embodiment of the present invention. With reference to FIGS. 3C and 3D, the reflecting layer 36 can be disposed on the inner surface of the housing 31 and has the opening 361 corresponding to the light emitting surfaces of the LED dies 33, and the wavelength converting material 37 can also be disposed on the inner surface or the outer surface of the housing 31 corresponding to the opening 361 (as shown in FIG. 3C). It is to be noted that the reflecting layers 36a and 36b are disposed interlacedly on the inner and outer surfaces of the housing 31, the opening 361 for light emission, however, should be prevented from being covered.

Moreover, FIG. 3F is a schematic view of the light emitting unit in yet another various aspect according to the second embodiment of the present invention. With reference to FIG. 3F, the wavelength converting material of the light emitting unit 3a may also be a phosphor tape T that is disposed on the outer surface and/or the inner surface of at least a part of the housing 31. The phosphor tape T is disposed on the outer surface of the housing 31 by attaching for example. The phosphor tape T includes, for example, an adhesive layer T1 and a phosphor layer T2 having the phosphor doped within, hence can be excited by the light of the LED die 33 so as to change the color of the light emitted from the light emitting unit 3a. It is to be noted that the phosphor tape T may have different compositions depending on different requirements.

Additionally, with reference to FIG. 3F, a light scattering element, a light refracting element, or a lamp house may be disposed between two adjacent LED dies 33. If the light scattering element or the light refracting element is disposed, its material can be transparent for changing the light path of the LED die 33 so as to help the light mixing of each LED die 33. If the lamp house is disposed, it would help concentrate the light emitting direction of the LED die 33. In FIG. 3F, the lamp house L is disposed on the periphery of each LED die 33 for example.

### Third Embodiment

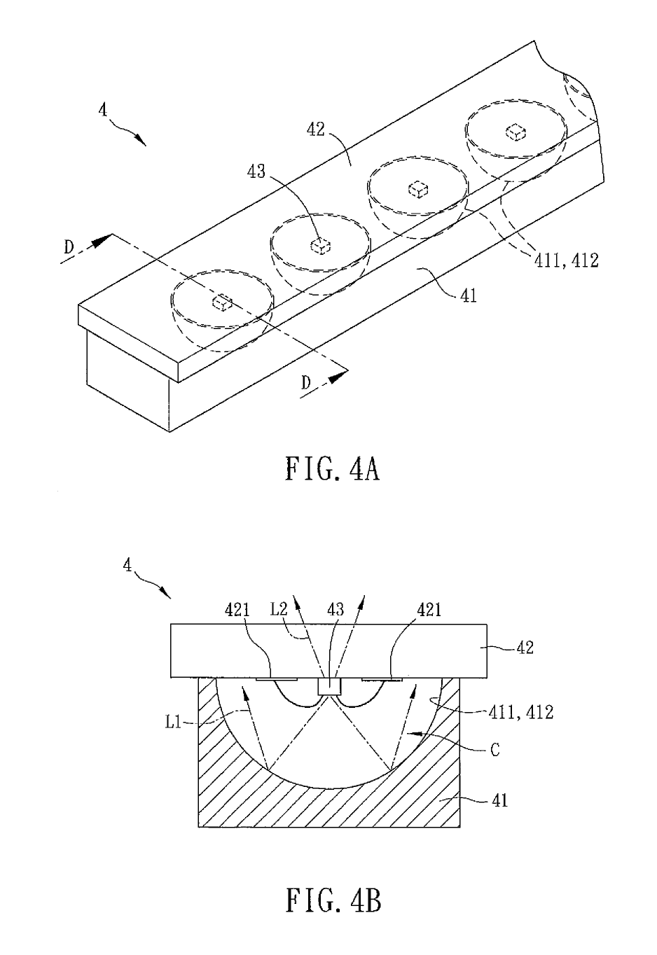

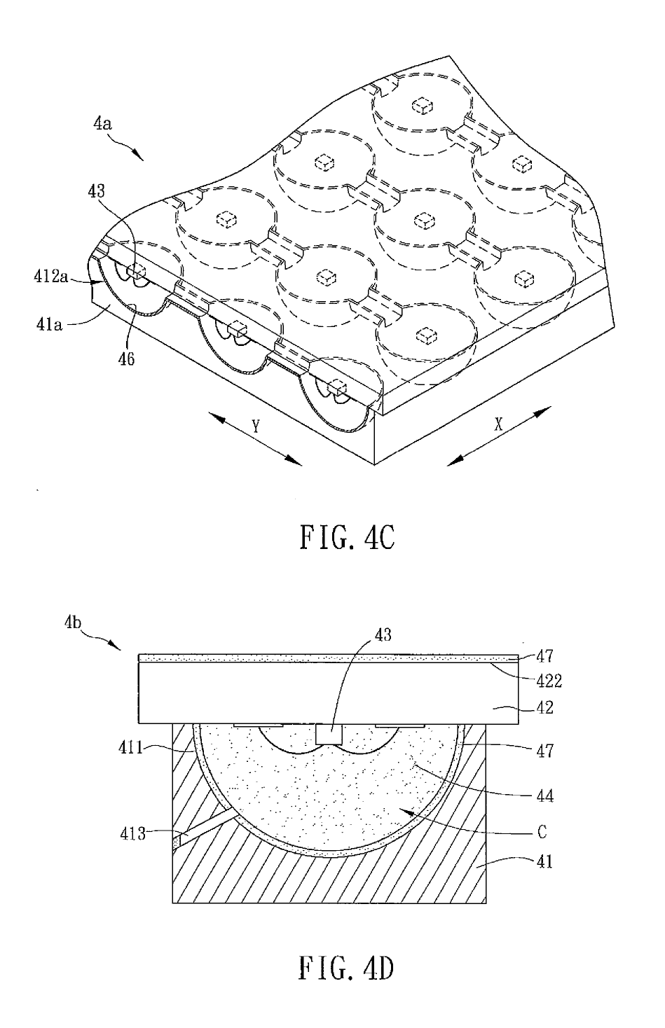

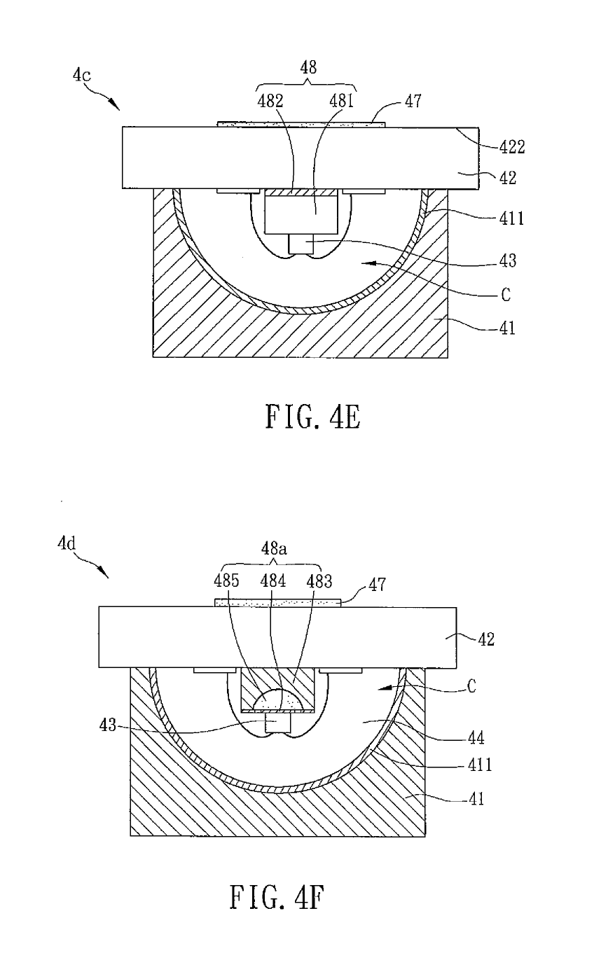

FIGS. 4A and 43 are schematic views of a light emitting unit according to the third embodiment of the present invention, in which FIG. 4B is a cross-sectional view of FIG. 4A along a line D-D. With reference to FIGS. 4A and 4B, the light emitting unit 4 according to the embodiment includes a housing 41, a substrate 42, and a plurality of LED dies 43.

The housing 41 is a metal housing or an alloy housing for example, so the housing 41 has the advantages of high reflectivity, fine heat dissipation effect and can be easily manufactured and formed. The inner surface of the housing 41 is a reflecting surface 411 for example, and the housing 41 and the substrate 42 form a chamber C; the shape of the housing 41 is not limited. The housing 41 has a plurality of concave parts 412 and the reflecting surface 411 is located on the surface of the concave part 412; the concave parts 412 are corresponding to the LED dies 43 for example. As a matter of course, the housing may have only a concave part 412 corresponding to a plurality of LED dies 43. In the embodiment, the chamber C is a non-airtight chamber for example, hence the gas or the air (both are fluid) can freely flow in the inside and outside of the chamber C so as to help heat dissipation.

The substrate 42 includes a circuit layer 421 and is at least partially transparent. The material of the substrate 42 includes glass, sapphire, quartz, polymer, or plastic for example. The substrate 41 is a glass circuit board for example.

The LED dies 43 that are disposed on the substrate 42 are located in the chamber C, and are electrically connected to the circuit layer 421. The reflecting surface 411 reflects at least a part of the light L1 emitted from the LED die 43 through the substrate 42, which means, the light emitting side of the light emitting unit 4 is on the substrate 42.

The light L1 emitted from a surface of the LED die 43 can be reflected by the reflecting surface 411 of the housing 41 and then emitted out through the substrate 42, and the light L2 emitted from another surface of the LED die 43 can be emitted out directly through the substrate 42, so as to increase the light utilization rate of the light emitting unit 4. Moreover, the curvature or the shape of the reflecting surface 411 changes as the shape of the housing 41 changes. The shape of the reflecting surface 411 may be, for example, a paraboloid, a hemispherical surface, or an elliptical surface. Its curvature can be designed according to the product need so as to control the direction of the light L1 emitted from the light emitting unit 4. For example, the light L1 can be a parallel light or a non-parallel light, and it can be emitted out from the light emitting surface of the substrate 42 with or without perpendicular to the light emitting surface for increasing the directivity of the light emitting unit 4.

FIG. 4C shows the light emitting unit 4 in another various aspect according to the embodiment. With reference to FIG. 4C, the housing 41a of the light emitting unit 4a may be formed by not only the metal or the alloy as mentioned above, and also the material having no light reflectivity such as polymer, glass, quartz, or ceramics, or by the transparent material. For that, however, a reflecting layer 46 used as a reflecting surface will have to be disposed for reflecting the light emitted from the LED die 43. The reflecting layer 46 can be disposed on a surface of the housing 41a facing the LED die 43 and/or a surface of the housing 41a away from the LED die 43. In this embodiment, the reflecting layer 46 is, for example, disposed on the surface of the housing 41a facing the LED die 43. Furthermore, the LED dies 43 are disposed on the substrate 41a in a two-dimensional array. It is to be noted that the concave parts 412a may or may not be connected to each other. The concave parts 412a are connected to each other in the direction Y herein and are not connected to each other in direction X for example but not limited to these.

FIG. 4D shows the light emitting unit 4 in another various aspect according to the embodiment. Referring to FIG. 4D, the difference between the light emitting unit 4b and the light emitting unit 4 is that the light emitting unit 4b further includes a gel or a fluid 44, and a wavelength converting material 47.

In FIG. 4D, the fluid 44 is a liquid for filling the chamber C, which is an airtight chamber and the fluid 44 needs or needs not to fill up the chamber C. The wavelength converting material 47 may be disposed on a light emitting surface 422 of the substrate 42 or a reflecting surface 411 of the housing 41, or doped in the fluid 44 or in the substrate 42. In the embodiment, the wavelength converting material 47 is disposed on the light emitting surface 422 of the substrate 42 and the reflecting surface 411 of the housing 41 at the same time for example. The wavelength converting material 47 may be a wavelength converting material layer or a wavelength converting material tape having the wavelength converting material, e.g. a phosphor tape. In the embodiment, the wavelength converting material 47 is, for example but not limited to, a fluorescent converting layer. The wavelength converting material 47 may be used to change the color of the light emitted from the light emitting unit 4b for increasing the applications of the light emitting unit 4b. If the phosphor tape is used for the wavelength converting material 47, the manufacturing efficiency and the product reliability can be increased.

By selecting the gel or the fluid 44 with a specified refractive index, for example, a refractive index between that of the LED die 43 and of the air, the light extraction efficiency of the LED die 43 can be increased. If the liquid gel or the fluid 44 is used, it can further enhance the heat dissipation effect of the light emitting unit 4b by heat convection.

In addition, the housing 41 may further have a hole 413 in the embodiment. By connecting the light emitting unit 4b and a pump (not shown), the fluid 44 may be filled in the chamber C through a hole 413. After that, the hole 413 can be closed. When the heat dissipation is carried out, the fluid 44 absorbing the heat generated by the LED dies 43 can be pumped out through the hole 413, and then the new fluid 44 can be filled in. By doing so, the heat dissipation effect of the light emitting unit 4b can be enhanced.

FIG. 4E is a schematic view of the light emitting unit in another various aspect according to the embodiment. Referring to FIG. 4E, the difference between the light emitting unit 4b and the light emitting unit 4 is that the light emitting unit 4b further includes a reflecting element 48 disposed on the substrate 42. The LED die 43 is disposed on the reflecting element 48. In the embodiment, the reflecting element 48 may have a carrier plate 481 and a reflecting layer 482. The carrier plate 481 may be a transparent material such as polymer, glass or quartz. Therefore, the path of the light emitted from the LED die 43 can be extended to increase the probability that the light emits through the substrate 42, so that a part of light emitted from the LED 43 can be prevented from being not able to emit out due to the total reflection of the substrate 42, hence increase the light utilization rate of the LED die 43. It is noted that the wavelength converting material may be disposed to or doped in the reflecting element 48.

In the embodiment, the reflecting layer 411 on the housing 41 is used as a reflecting surface, and the wavelength converting material 47 is disposed on the light emitting surface 422 but not limited to these. Furthermore, the curved surface formed by the reflecting layer 411 of the housing 41 has a light concentrating spot (or the focus of the reflecting surface) approximately located to a certain position on the light emitting surface 422 of the substrate 42, so the wavelength converting material 47 is disposed around the light concentrating spot for saving the amount and the cost of the wavelength converting material 47. In addition, the reflecting layer 411 of the housing 41 may farther include a scattering structure (e.g. the reflecting layer 411 with a rough surface or the scattering lens, not shown) to make the light emitted from the LED die 43 through the substrate 42 more even.

FIG. 4F is a schematic view of the light emitting unit 4c in another various aspect of the embodiment. The reflecting element 48a of the light emitting 4d may also have a reflecting cup 483, which may be made of the material having light reflectivity, for example, metal or alloy. In addition, the reflecting cup 483 may be made of the material having no light reflectivity, for example, polymer, glass, quartz, or ceramics, and the reflecting element 48a further has a reflecting layer. In the embodiment, the material of the reflecting cup 483 is metal or alloy for example. In addition, the reflecting element 48a may further have a holding member 484 that is, for example, a meshed structure or a plate with holes. The holding member 484 can hold the LED die 43 to an opening of the corresponding reflecting cup 483. Moreover, the reflecting element 48a may further include a gel 485, which is filled in the reflecting cup 483, and the LED die 43 is disposed on the gel 485.

What is worth to be mentioned is that the gel 485 can be directly filled in to the reflecting cup 483, or when the gel 44 is filled in the chamber C, the gel 485 can also be filled in the reflecting cup 483 through the hole of the holding member 484 at the same time, such that the gel 485 and the gel 44 are made of the same material. As a matter of course, if it is the fluid filled in the chamber, it can also be filled in the reflecting cup 483 at the same time.

Therefore, by selecting the gel 485 or the fluid with a specified refractive index, such as a refractive index between that of the LED die 43 and of the air, a part of the light emitted from the LED die 43 can be prevented from being not able to emit out due to the total reflection of the substrate 42, and the path of the light emitted from the LED die 43 is further extended so as to increase the probability that the light emitted from the back of the LED die 43 penetrates through the substrate 42, hence increase the light utilization rate of the LED die 43.

### Fourth Embodiment

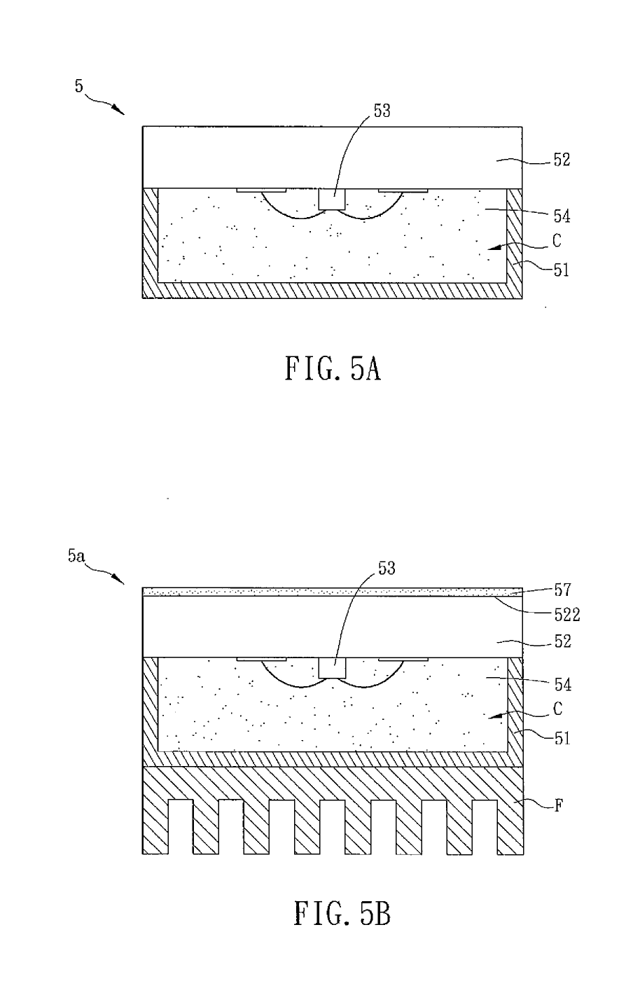

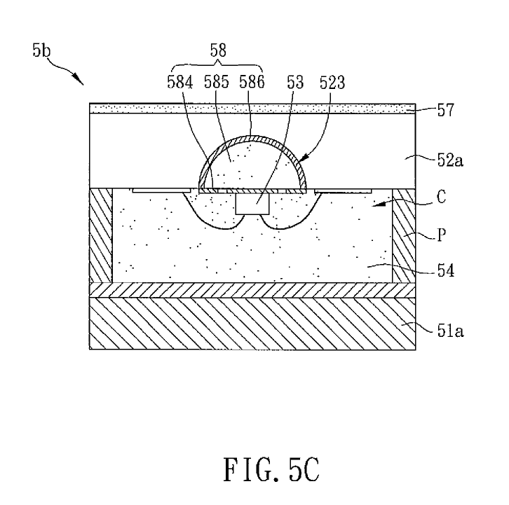

FIG. 5A is a schematic view of the light emitting unit 5 according to the embodiment. The light emitting unit 5 includes a housing 51, a substrate 52, a plurality of LED dies 53, and a gel or a fluid 54. Since the figure is presented in a cross-sectional view, only an LED die 53 can be seen. The substrate 52, and the gel or the fluid 54 in the embodiment have the same effects and technical features as the substrate 42 and the gel or the fluid 44 of the light emitting unit 4 in the third embodiment, the detailed description will thus be omitted. The light emitted from the LED die 53 can be reflected by the housing 51 through the substrate 52 and emitted out from the light emitting unit 5.

The material of the housing 51 is metal or alloy. The cross-section of the housing 51 can be approximately a U-shape and the housing 51 combines with the substrate 52 (e.g. by attaching, cogging, locking, or screwing) to form the chamber C. The gel or the fluid 54 is filled in the chamber C.

Additionally, FIG. 5B is a schematic view of the light emitting unit in another various aspect according to the embodiment. With reference to FIG. 5B, the light emitting unit 5a may further include a heat dissipating unit F and a wavelength converting material 57. The heat dissipating element F may be a heat dissipating plate, a heat pipe, fins, or a MEMS heat dissipating system. The heat dissipating element F is connected to and contacts with the housing 51. Since the housing contacts the fluid 54 in the chamber C and the LED die 53 contacts the fluid 54, the heat energy generated by the light emitting unit 5a would be transmitted to the heat dissipating element F from the LED die 53 through the fluid 54 and the housing 51 by thermal conduction. Then the heat dissipating element F dissipates the heat energy to the air outside. Thus, the heat dissipating efficiency of the light emitting unit 5a can be increased so as to ensure the product quality of the light emitting unit 5a.

The wavelength converting material 57 is disposed on the light emitting surface 522 of the substrate 52, so the light emitted from the light emitting unit 5a can be mixed to be, for example, a white light. The material of the wavelength converting material 57 is the same as that in the above-mentioned embodiment, thus the detailed description thereof will be omitted.

With reference to FIG. 5C, the difference between the light emitting unit 5b and the light emitting unit 5a is that the housing 51a is a plate-like metal housing combining with a plate-like substrate 52a by an adhesive P to form the chamber C. Besides, the substrate 52a of the light emitting unit 5b further has a concave part 523, and a reflecting element 58 is disposed on the concave 523. The reflecting element 58 includes a reflecting layer or a lamp house 586, and a holding member 584 for holding the LED die 53 on the concave 523.

In addition, the gel 585 can be directly filled in the reflecting element 58, or when the gel 54 is filled in the chamber C, the gel 585 can be filled in the concave part 523 through the opening of the holding member 584. As a matter of course, if it is the fluid filled in to the chamber C, it can also be filled in the reflecting element 58b at the same time. Similarly, by filing the gel 585 or the fluid with specified refractive index in the concave part 523 and reflecting the light emitted from the LED die 53 by the reflecting layer 586, the light utilization rate of the LED die 53 can be increased.

As shown in FIGS. 4A and 4B, the light emitting units 5, 5a, and 5b of the embodiment are arranged in a straight line or in a two-dimensional array. Since the structure and effect of the straight line or the two-dimensional array are described in the third embodiment, the detailed description thereof will be omitted.

### Fifth Embodiment

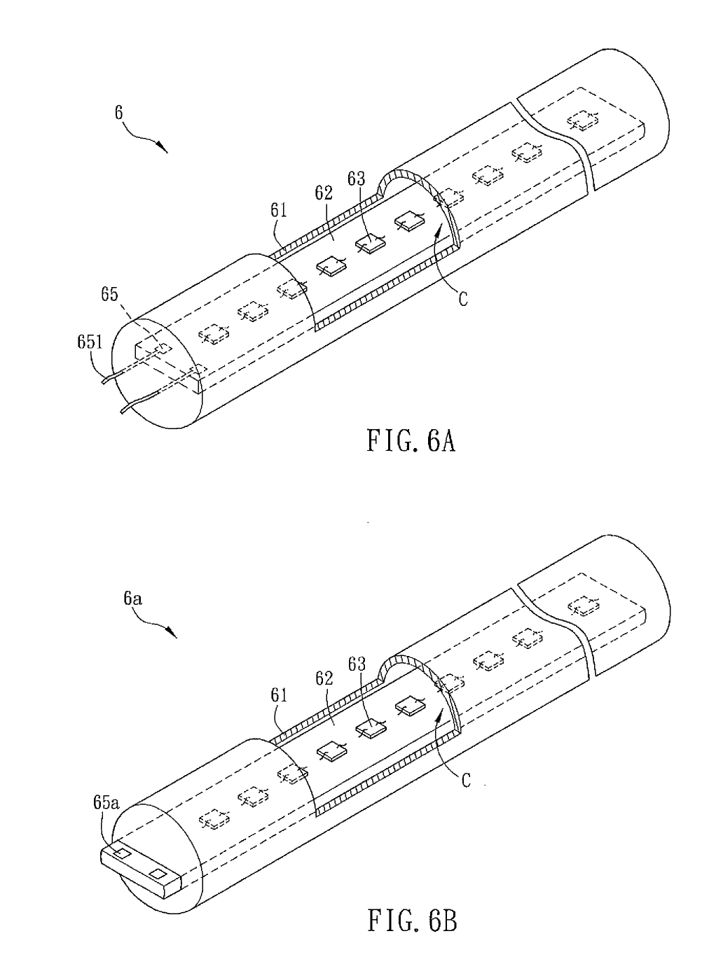

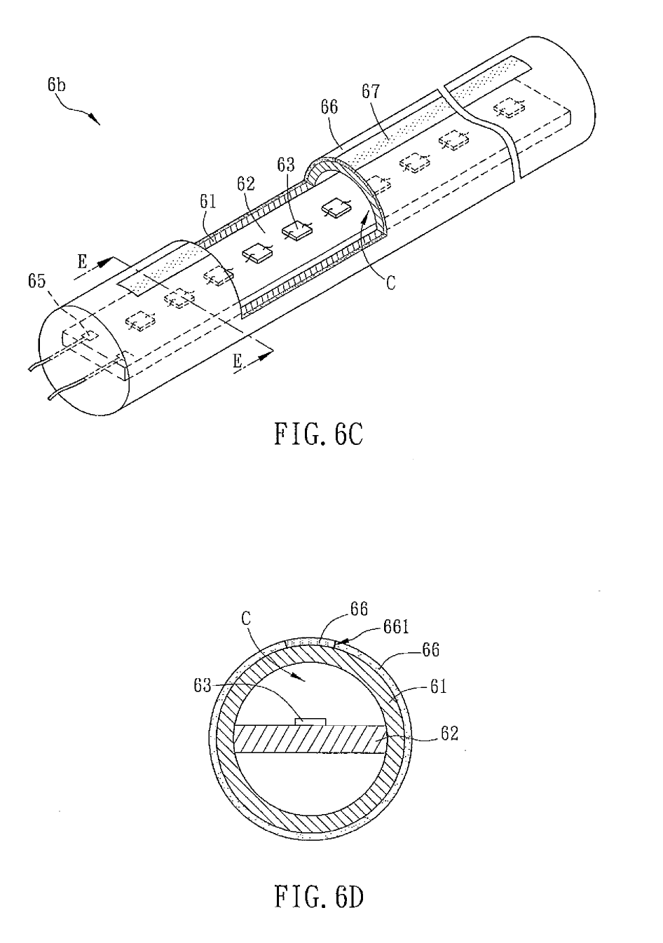

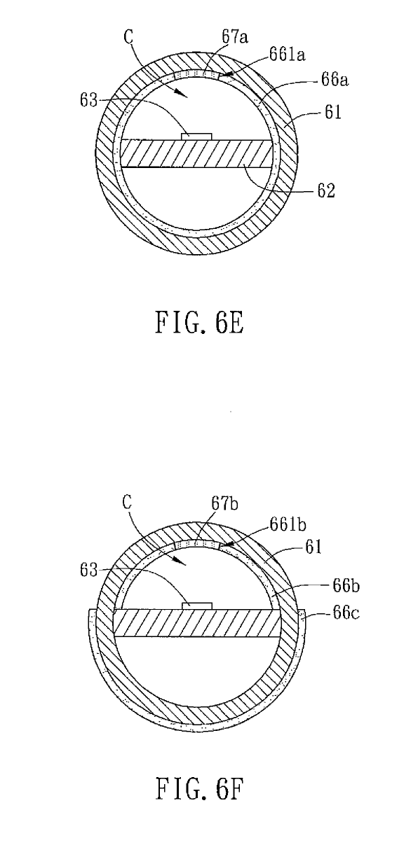

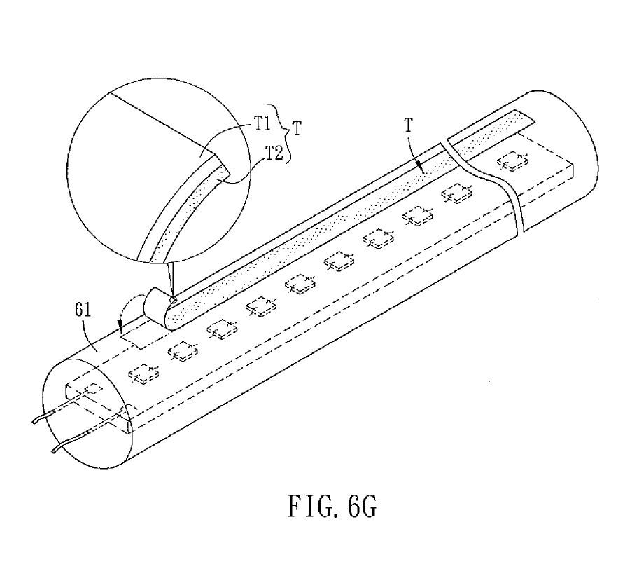

FIG. 6A is a schematic view of a light emitting unit according to the fifth embodiment of the present invention. With reference to FIG. 6A, a light emitting unit 6 includes a transparent tube 61, a substrate 62, and a plurality of LED dies 63. The chamber C is located in the transparent tube 61. To illustrate easily, an opening is cut on the transparent tube 61 for understanding the internal structure.

The transparent tube 61 is at least partially transparent. In other words, it may include a transparent part and a non-transparent part, which means, the transparent tube 61 can be partially transparent or partially non-transparent. Of course, it can also be entirely transparent. The chamber C may be vacuum or filled with the fluid, which can be liquid (e.g. oil or solvent), gas (e.g. inert gas, air, or nitrogen gas), or oil-based fluid (that the refractive index thereof may be larger than 1.3). Furthermore, the chamber C may also be filled with a gel such as a liquid gel or an elastic gel. In addition, if the surface of the transparent tube 61 is a curved surface, the refractive index of the fluid or the gel may be larger than or equal to the refractive index of the transparent part of the transparent tube 61, thereby a light concentration function can be generated such that the light emitting surface of the transparent tube 61 forms an effect similar to the convex lens. In the embodiment, the housing elements are connected to each other to form the transparent tube 61 by attaching, cogging, locking, melting, or gluing. The gluing method includes UV curing after sealing, thermal curing after sealing, natural drying after sealing, and seal curing after installing the housing element.

In the embodiment, the material of the transparent part of the transparent tube 61 is, for example, at least one of polymer, glass, and quartz, and the material of the non-transparent part is, for example, at least one of polymer, ceramics, and metal. The polymer may be at least one of polystyrene (PS), polycarbonate (PC), methylstyrene (MS), polymethylmethacrylate (PMA), and acrylonitrile butadiene styrene (ABS). Additionally, if the transparent tube 61 is mainly made of metal material, the light emitting surface of the transparent tube 61 corresponding to the LED die 63 has an opening, which is the transparent part for the light to emit out. Since the metal itself has the advantages such as high reflectivity, fine heat dissipation effect, and easy manufacturing, the applications of the light emitting unit 6 can be increased.

A plurality of scattering centers that can be mixed in the transparent tube 61 may be scattering particles or scattering bubbles for increasing the light diffusion effect. The material of the scattering particle can be an organic scattering center or an inorganic scattering center having a different refractive index from transparent tube 61. The material of the inorganic scattering center may be BaSO4, SiO2, or Al2O3. In addition, the transparent tube 61 is, for example, a strip type tube and its cross-sectional shape is circle, ellipse, triangle, quadrilateral, polygon, or irregular shape for example. In the embodiment, the cross-sectional shape of the transparent tube 61 is circle.

The substrate 62 is disposed in the chamber C of the transparent tube 61 and can be, for example, a glass substrate, a resin substrate, a ceramic substrate, or a metal substrate. The substrate 62 may have a circuit layer.

The LED die 63 is disposed on a surface of the substrate 62 and can be electrically connected to the substrate 62 by flip-chip or wire-bonding.

In the embodiment, the light emitting unit 6 may further include two connecting electrodes 65 electrically connected to the LED die 63, and the connecting electrodes 65 can be disposed on an end of the substrate 62 or two ends of the substrate 62 respectively. The connecting electrodes are electrically connected to the exterior of the transparent tube 61. In the embodiment, the connecting electrodes 65 are electrically connected to the exterior of the transparent tube 61 through a metal wire 651, respectively. What is worth to be mentioned is that the plurality of light emitting units 6 can be connected to each other in series by the connectors disposed on the outside of the transparent tube 61 or other electrically-connecting mechanisms, in which the connector or the electrically-connecting mechanism is electrically connected to the connecting electrode 65. Additionally, FIG. 6B is schematic view of the light emitting unit in another various aspect according to the embodiment. Referring to FIG. 6B, the connecting electrode 65a may be extended to the exterior of the transparent tube 61.

Please again refer to FIG. 6A, since the LED dies 63 are located in the chamber C of the transparent tube 61, in the light emitting unit 6 of the embodiment, the LED dies 63 do not need to be completely covered by the molding compound with high thickness. The transparent tube 61 is capable of protecting the LED dies 63 from the environmental factor such as moisture or dust and preventing the wire connected between each LED die 63 and the substrate 62 from deforming or breaking due to squeezing or dragging. Additionally, without the separation of high thickness gel, the heat is dissipated from the substrate 62 below the LED die 63 or from the top of the LED dies 63. If it is the fluid or the gel filled in the transparent tube 61, the heat energy can be transmitted by heat convection effect of the fluid or the gel, such that the heat dissipation effect can be further enhanced.

### Sixth Embodiment

FIG. 6C is a schematic view of a light emitting unit in a various aspect according to the sixth embodiment of the present invention. FIG. 6D is a cross-sectional view of FIG. 6C along a line E-E. With reference to FIGS. 6C and 6D, for easily understanding the internal structure, an opening is cut on the transparent tube. The difference between the light emitting unit 6b in the embodiment and the light emitting unit 6 in the fifth embodiment is that the light emitting unit 6b further includes a reflecting part and a fluorescent converting material 67. The reflecting part can be a part of the transparent tube 61, or a reflecting layer 66 may be added to the exterior of the transparent tube 61 as described in the embodiment. The reflecting layer 66 may be located on an outer surface or an inner surface of the transparent tube 61.

As shown in FIGS. 6C and 6D, in the embodiment, the reflecting layer 66 is disposed on the outer surface of the transparent tube 61 and has at least one opening 661 corresponding to a light emitting surface of the LED dies 63. The material and the forming method of the reflecting layer 66 are described in the above-mentioned embodiment, so the detailed description thereof will be omitted. The wavelength converting material 67 can be disposed on the partial outer surface and/or partial inner surface of at least a part of the transparent tube 61, or directly doped in the transparent tube 61 and/or in the gel or the fluid as described in the above-mentioned embodiment. In the embodiment, the wavelength converting material 67 is disposed correspondingly to the opening 661 and is located on the outer surface of the transparent tube 61. The fluorescent converting material 67 includes at least a yellow fluorescent converting material, a red fluorescent converting material, a green fluorescent converting material, or a blue fluorescent converting material.

By disposing the reflecting layer 66, the light emitting direction of the light emitting unit 6b can be concentrated, and the light emitted from the LED dies 63 can be mixed by the reflecting layer 66 and then emitted out, such that the light emitting unit 6b can emit out a light uniformly. Additionally, the color of the light emitted from the light emitting unit 7 can be changed by the wavelength converting material 67.

FIG. 6E is a schematic view of a light emitting unit in a various aspect according to the sixth embodiment of the present invention. With reference to FIG. 6E, the reflecting layer 66a can be disposed on the inner surface of the transparent tube 61 and has the opening 661a corresponding to the light emitting surface of the LED dies 63, and the wavelength converting material 67a can be disposed on the inner or outer surface of the transparent tube 61 corresponding to the opening 661a. In the embodiment, the wavelength converting material 67a is disposed on the inner surface of the transparent tube 61 corresponding to the opening 661a for example. Moreover, FIG. 6E is a schematic view of a light emitting unit in a various aspect according to the sixth embodiment of the present invention. With reference to FIG. 6F, the reflecting layers 66b and 66c can be disposed on the inner and outer surfaces of the transparent tube 61 at the same time. It is to be noted that the reflecting layers 66b and 66c are disposed interlacedly on the inner and outer surfaces of the transparent tube 61, and the opening 66 la for light emission should be prevented from being covered.

FIG. 6G is a schematic view of a light emitting unit in a various aspect according to the sixth embodiment of the present invention. With reference to FIG. 6G, the wavelength converting material may also be replaced by a phosphor tape T having the wavelength converting material. The phosphor tape T is disposed on the outer surface and/or inner surface of at least a part of the transparent tube 61. Regarding to this, the phosphor tape T is disposed on the outer surface of the transparent tube 61 by attaching for example. The phosphor tape T includes an adhesive layer T1 and a phosphor layer T2 doped with the phosphor for changing the color of the emitted light. It is to be noted that the phosphor tape T may have difference compositions depending on different needs.

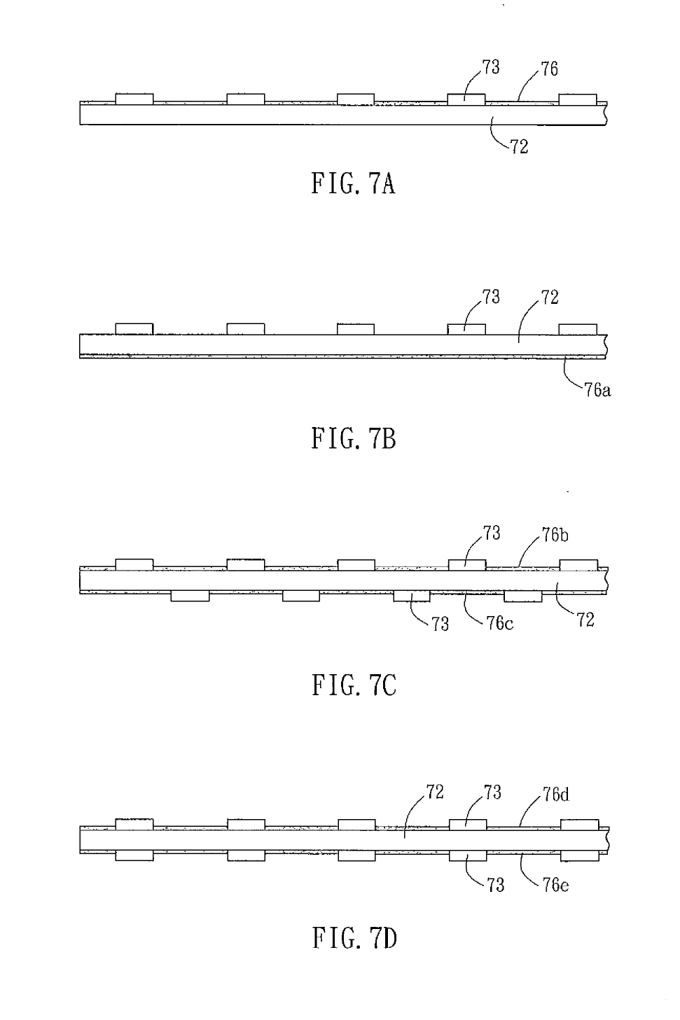

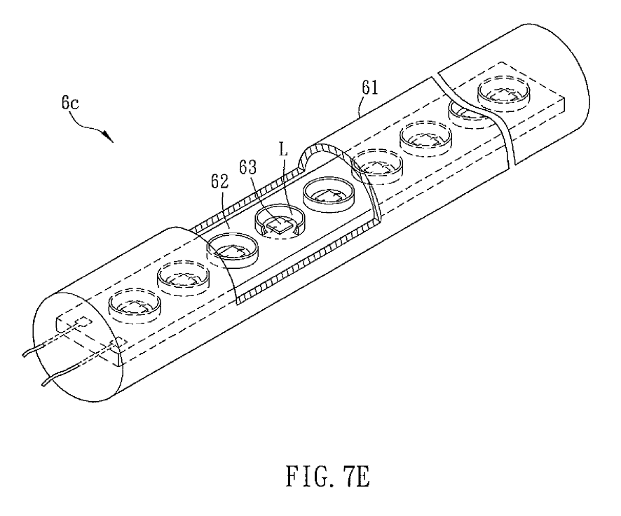

Moreover, the above-mentioned reflecting layer is disposed on the transparent tube for example. The reflecting layer, however, may also be disposed on the surface of the substrate. FIGS. 7A to 7D are the cross-sectional views of the long axis of the substrate 72. With reference to FIGS. 7A to 7D, the transparent tube is slipped in all of the following figures for clear illustration, but the substrate 62 is still disposed in the transparent tube in application.

As shown in FIGS. 7A to 7D, a plurality of LED dies 73 are disposed on a surface or another surface of the substrate 72. Similar to the above-mentioned embodiment, the LED die 73 can be disposed on the substrate 72 by flip-chip or wire-bonding. The LED die 73 is disposed on the substrate 72 by flip-chip for example.

Referring to FIG. 7A, the reflecting layer 76 is disposed to the peripheries of the LED dies 73 on the substrate 72. The light emitted from the LED die 73 to the substrate 72 can be reflected by the reflecting layer 76. By doing so, the utilization rate of the light emitted from the LED dies 73 can be increased. The material of the reflecting layer 76 is the same as that of the above-mentioned reflecting layer, so the detailed description thereof will be omitted.

In addition, with reference to FIG. 7B, if the substrate 72 is a transparent substrate, the reflecting layer 76a can be disposed on the surface of the substrate 72 that does not face the LED dies 73 for reflecting the light emitted from the LED dies 73.

With reference to FIG. 7C, the LED dies 73 can be interlacedly disposed on the opposite two surfaces of the substrate 72. Regarding to this, the reflecting layers 76b and 76c can be disposed on the two surfaces of the substrates, respectively, and around the LED dies 73. Additionally, with reference to FIG. 7D, the respective LED die 73 may also be disposed on the two surfaces of the substrate 72 correspondingly. In this case, the reflecting layers 76d and 76e can be disposed on the two surfaces of the substrate 72, respectively, and around the LED dies 73. It is to be noted that the disposition of the reflecting layer is not limited to these, and it can also be disposed to the peripheries of some LED dies 73 according to different designs.

In addition, with reference to FIG. 7E, the light emitting unit 6c can further include a light scattering element, a light refractive element, or a light reflecting element that is disposed between two LED dies 73. In the embodiment, the light path can be changed by disposing a reflecting element L (e.g. a lamp house) to the peripheries of the LED dies 73, so as to reflect and concentrate the light emitting directions of the LED dies 73.

### Seventh Embodiment

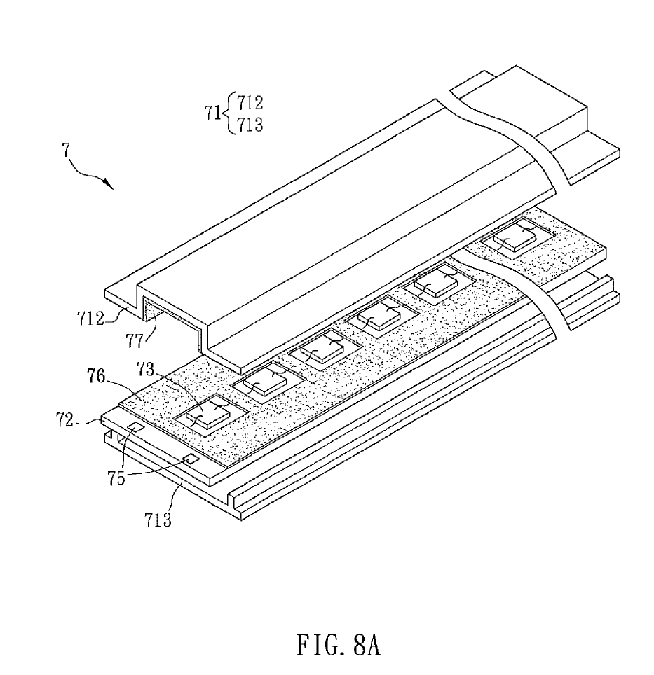

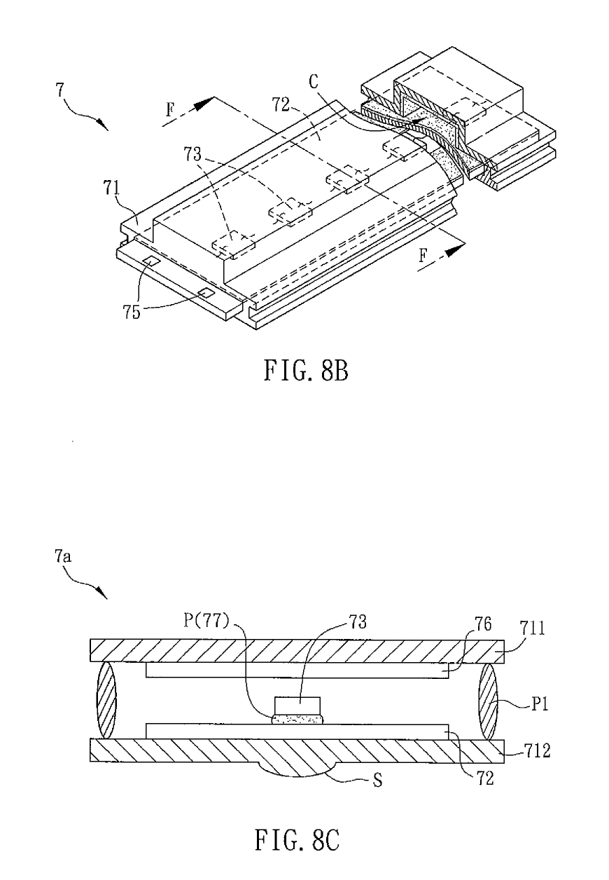

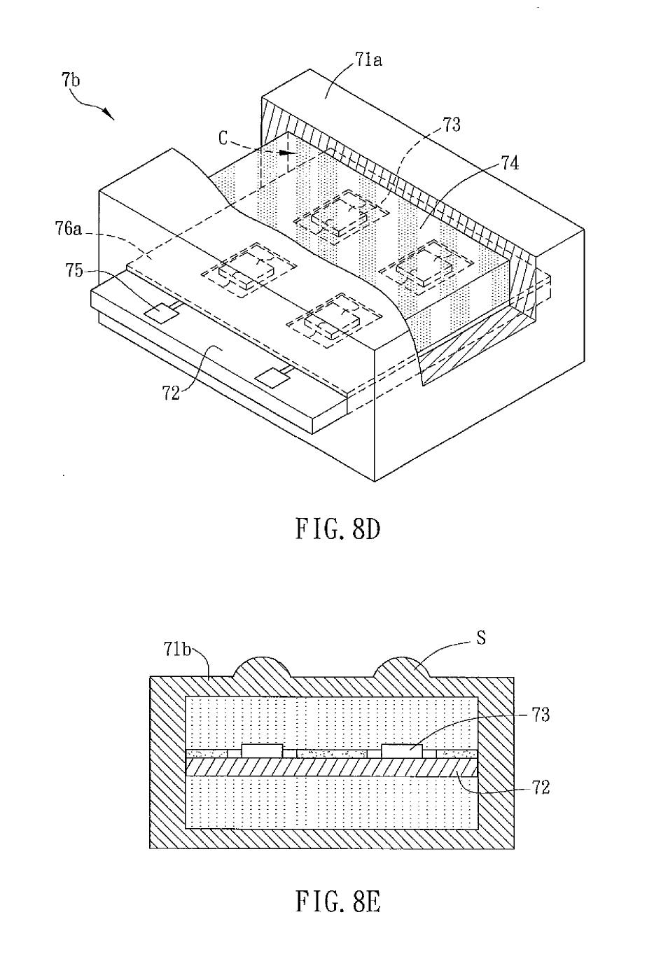

FIGS. 8A and 8B are schematic views of a light emitting unit according to the seventh embodiment of the present invention, in which FIG. 8B is a schematic assembled view of FIG. 8A. The difference between the light emitting unit 7 of the seventh embodiment and the light emitting unit 6 of the sixth embodiment is that the chamber of the light emitting unit 7 is formed between two housing elements 712 and 713. In the embodiment, the housing elements 712 and 713 are plate-like housings. On the edge of the housing elements 712 and 713, there may be a protruding part or a depression part for assembling the two housing elements 712 and 713.

The housing elements 712 and 713 may be partially transparent, partially non-transparent, or entirely transparent. The upper housing element 712 in the embodiment is transparent and the lower housing element 713 is non-transparent for example but not limited to these. Furthermore, at least one of the housing elements 712 and 713 may have a plurality of scattering centers. Since the material of the scattering centers is described in the previous embodiment, the detailed description thereof will thus be omitted.

After the housing elements 712 and 713 are disposed correspondingly, they can be combined by gluing or melting to form the chamber C. The gluing method includes UV curing after sealing, thermal curing after sealing, or natural drying after sealing. Moreover, after the housing elements 712 and 713 are locked or cogged together, they may be combined by gluing or melting. Similarly, the chamber is filled with the gel or the fluid, and since the properties of the gel or the fluid have been described in the previous embodiment, the detailed description thereof will be omitted.

The plurality of LED dies 73 and the two connecting electrodes 75 are disposed on the substrate 72. The LED dies 73 are arranged one-dimensionally and the substrate 72 are disposed between the two housing elements 712 and 713.

A reflecting layer 76 may be disposed or formed on the substrate 72. Of course, the reflecting layer 76 may be disposed on the partial outer surface and/or the partial inner surface of at least one of the housing elements 712 and 713. Additionally, a wavelength converting material 77 may be disposed or formed on the partial outer surface and/or the partial outer surface of at least one of the housing elements 712 and 713, and/or doped in the housing elements 712 and 713. In the embodiment, the wavelength converting material 77 is disposed on the inner surface of the housing element 712 for example but not limited to this. The above-mentioned embodiment may be used as an example in other aspects, and surely the wavelength converting material can also be replaced by the phosphor tape.

FIG. 8C is a schematic view of the light emitting unit 7 in another various aspect of the seventh embodiment. The difference between the light emitting unit in FIG. 8C and the light emitting unit 7 is that the substrate 72 is made of transparent material, the LED die 73 is disposed on the substrate 72 by a die attach adhesive P, and the wavelength converting material 77 may be doped in the die attach adhesive P or disposed on a side of the die attach adhesive P. Regarding to this, the wavelength converting material 77 is doped in the die attach adhesive P for example. Other than that, the housing elements 712 and 713 of the light emitting unit 7a are in a flat-plate shape and attached to each other by gel P1. The housing element 712 has a reflecting part, for example, a reflecting layer 76, and of course, it can also be the housing element 712. Moreover, the housing 712 may further include a transparent part, and the housing element 713 is made of transparent material for example. Additionally, the housing element 712 may further include a lens structure S, respectively, corresponding to each LED die 73, so as to gather the light from the LED dies 73.

Moreover, FIG. 8D is another various aspect of the light emitting unit 7. With reference to FIG. 8D, the difference between the light emitting unit 7b and the light emitting unit 7 is that the chamber C is located in a hollow housing 71a. The shape of the hollow housing is not limited. For example, its cross-sectional shape may be circle, ellipse, triangle, quadrilateral, polygon, irregular shape, or different various aspects according to different designs. The hollow housing 71a may also have a plurality of scattering centers as described in the previous embodiment, thus the detailed description thereof will be omitted. Additionally, the hollow housing 71a may be partially transparent, partially non-transparent, or entirely transparent. The hollow housing 71a has a reflecting part for example. The reflecting part is a reflecting layer 76a disposed on the substrate 72. Of course the reflecting layer 76a may be disposed on an outer surface and/or an inner surface of a part of the hollow housing 71a. The wavelength converting material may be disposed on at least a part of the outer surface and/or at least a part of the inner surface of the hollow housing 71a, and/or doped in the hollow housing 71a, and the detailed description thereof will be omitted herein. Furthermore, the chamber C of the hollow housing 71a may also be filled with the fluid or the gel 74 to enhance heat dissipation effect of the LED dies 73.

FIG. 8E is a various aspect of the light emitting unit 7b. As shown in FIG. 8E, the hollow housing 71b may have a lens structure S corresponding to the outer surface or the inner surface of the housing on each LED die 73. The light emitted from the LED die 73 generates a light convergence effect through the lens structure S. Regarding to this, the lens structure S is disposed on the outer surface of the hollow housing 71b for example but not limited to this.

### Eight Embodiment

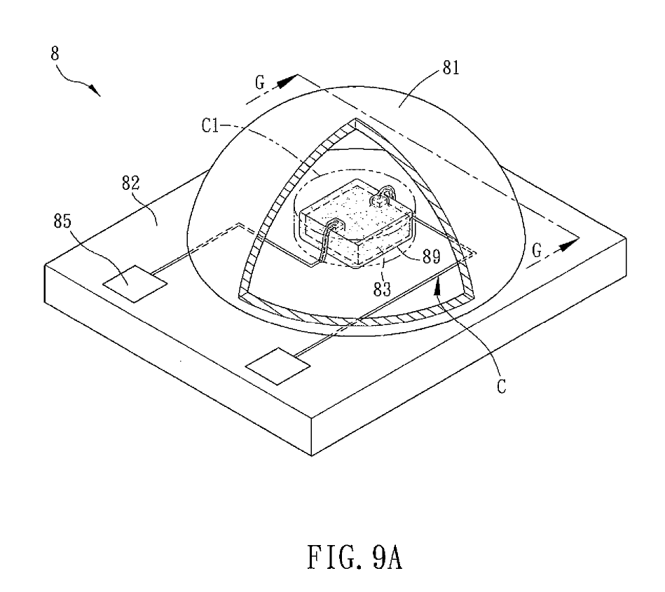

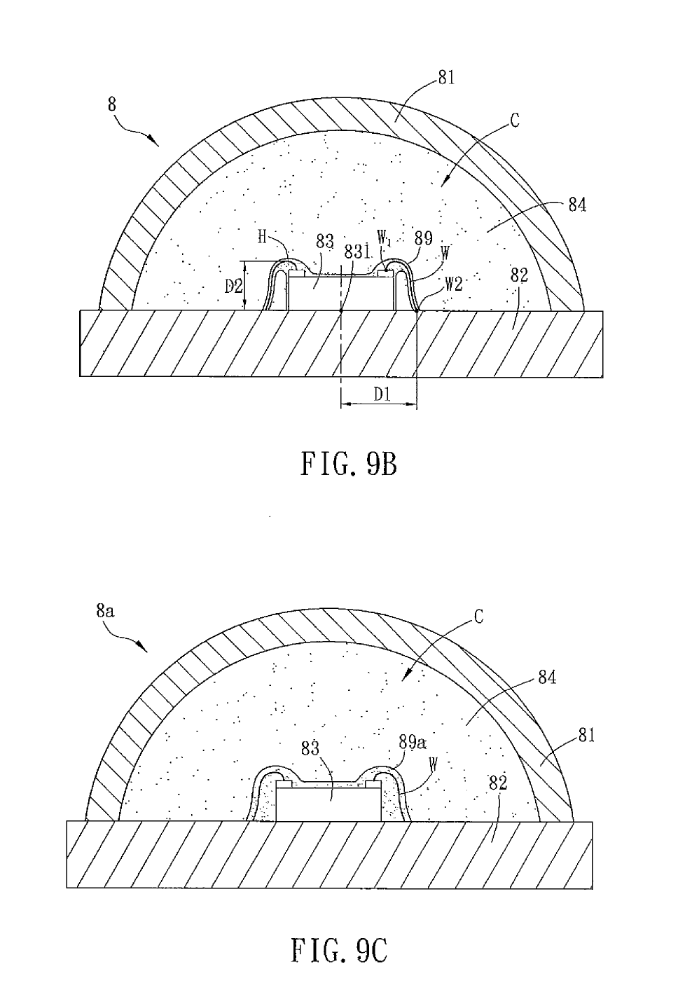

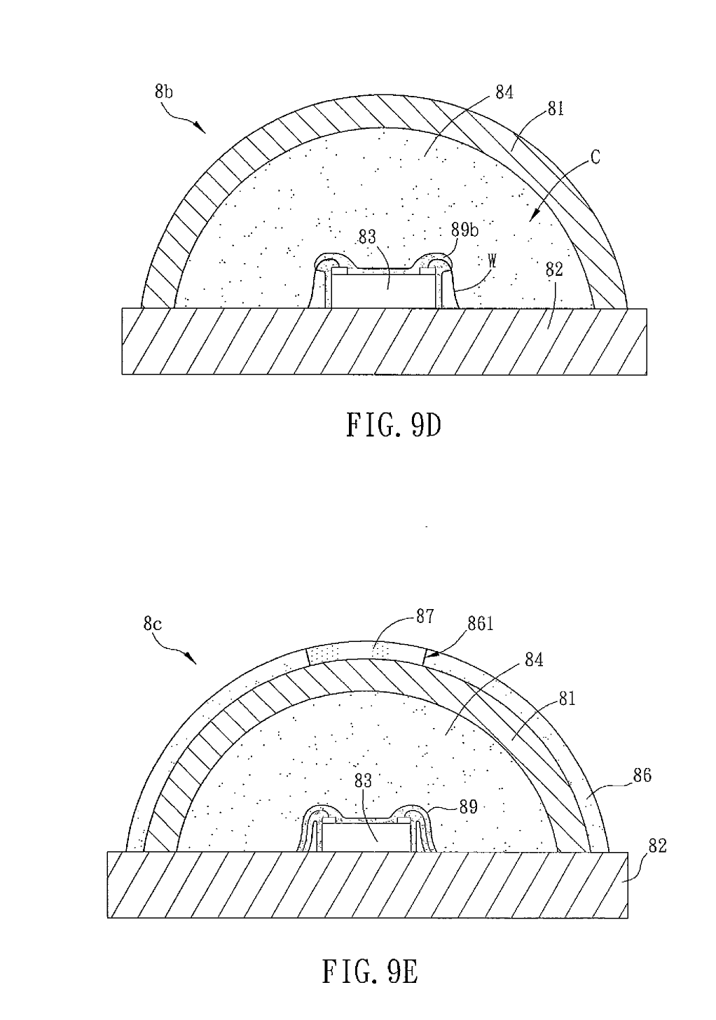

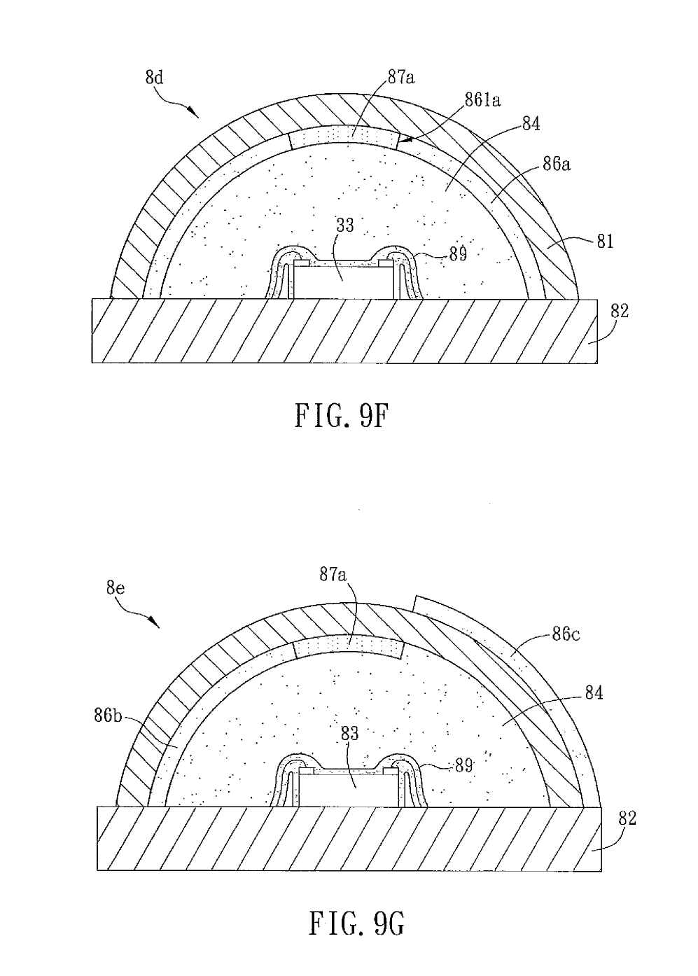

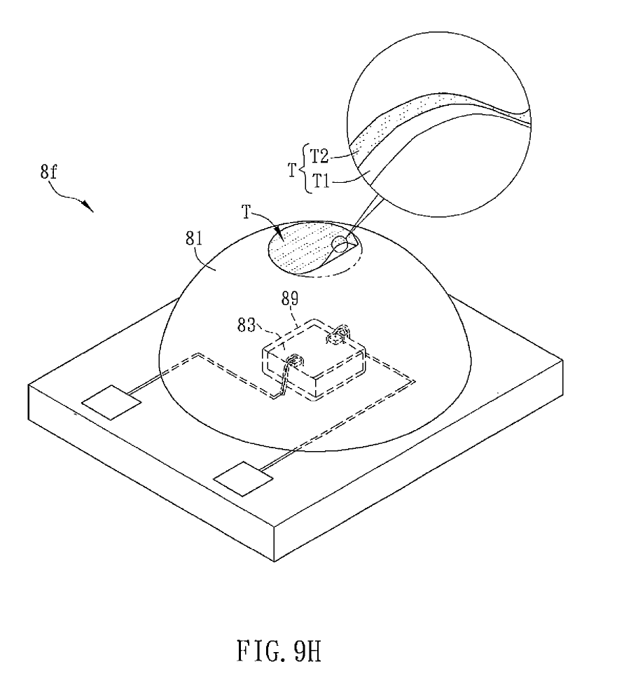

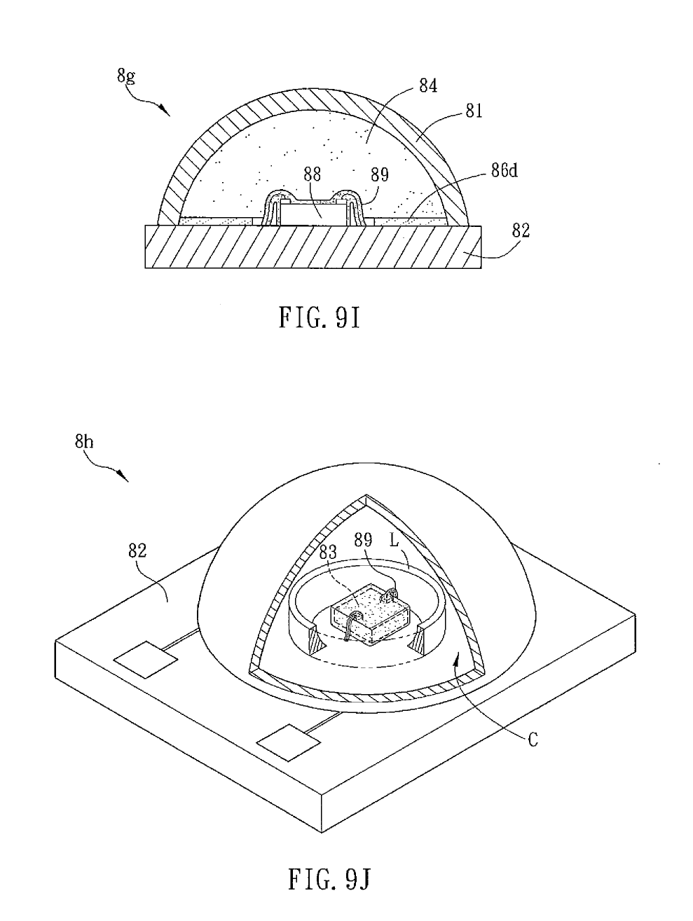

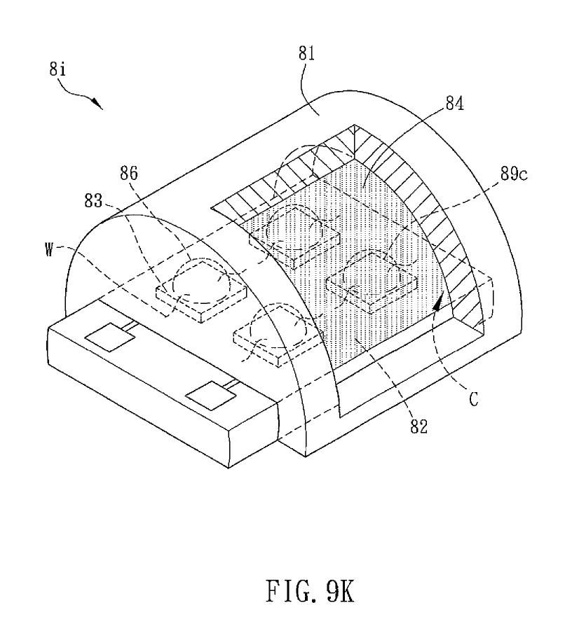

FIGS. 9A to 9K are schematic views of a light emitting unit in different aspects according to an eighth embodiment of the present invention.

FIG. 9B is a cross-sectional view of FIG. 9A along a line G-G. With reference to FIGS. 9A and 9B, the light emitting unit 8 of the embodiment includes a housing 81, a substrate 82, an LED die 83, a fluid 84 and a molding compound 89. The housing 81 forms the chamber C with the substrate 82. The LED die 83 is disposed on the substrate 82 and located in the chamber C. The fluid 84 is filled in the chamber C. The various aspects of the housing 81, substrate 82, LED die 83, and fluid 84 have been respectively illustrated in the previous embodiments, so the detailed description thereof will be omitted. In the embodiment, the housing 81 is a transparent housing and the substrate 82 is a printed circuit board (PCB) for example.

The molding compound 89 covers at least a part of the LED die 83, which means, the molding compound may or may not entirely cover the LED die 83. In the embodiment the molding compound 89 does not entirely cover the LED die 83 for example.

The molding compound 89 can cover the light emitting surface of the LED die 83 or cover the contact point contacting the LED die 83 and at least one wire. The molding compound 89 does not entirely cover the wire W and partially covers the LED die 83 to enhance the light emitting efficiency of the LED die 83 and protect the contact point contacting the light emitting surface of the LED die 83 and the wire. A first end W1 of the wire W is connected to the LED die 83 and a second end W2 of the wire W is connected to the substrate 82. The wire W is formed by wire-bonding and has a highest point H opposite to the substrate 82. A first distance D1 is between the second end W2 of the wire W and the center point 831 of the LED die 83, and a second distance D2 is between the highest point H of the wire W and the substrate 82. It is noted that the center point 831 of the LED die 83 is the geometric center point of the surface connecting the LED die 83 and the substrate 82. The molding compound 89 at least covers a part of the LED die 83, and the total volume of the molding compound 89 and the LED die 83 is smaller than the volume of a cylinder C1 formed by the first distance D1 and the second distance D2. The first distance D1 is the radius of the cylinder C1 and the second distance D2 is the height of the cylinder C1. In the embodiment, the molding compound 89 can be formed by dispensing. After dispensing, the molding compound 89 may flow down to the substrate 82 from the highest point H along the wire W and form a thin layer to cover the wire W. For example, the molding compound 89 covers entirely the LED die 83 and the wire W, but a gap is still formed between the wire W and the substrate 82. Moreover, the molding compound 89 may be a multilayer material with refractive indexes, in which the refractive indexes are sorted from large to small in accordance with the distance between the LED dies 83 from close to far. According to such property of the molding compound 89, the light emission range of the LED dies 83 can be increased, and the reduction in light extraction efficiency due to the total reflection easily taken place between the LED dies 83 can be prevented so as to enhance the light extraction efficiency of the light emitting unit 8.

The molding compound 89 can be disposed in different aspects. With reference to FIG. 9C, in the light emitting unit 8a, the molding compound 89a may also be extended between the wire W and the substrate 82, such that there is no space between the LED die 83 and the wire W. Furthermore, referring to FIG. 9D, in the light emitting unit 8b, at least a part of the wire W can also exposed from the molding compound 89b.

Please again refer to FIG. 9A, the light emitting unit 8 further includes at least two connecting electrodes 85 in the embodiment. The connecting electrodes 85 are electrically connected to the LED die 83. The connecting electrode 85 may be disposed on an end of the substrate 82, on two ends of the substrate 82 respectively, or to any position on the substrate 82, and the connecting electrode 85 is disposed on the outside of the housing 81. In the embodiment, the connecting electrodes 85 are disposed on an end of the substrate 82 for example.

To sum up, since the LED die 83 is located in the chamber C of the housing 81, the housing 81 can thus protect the LED die 83 from the environmental factor such as moisture or dust. Therefore, the molding compound 89 of the light emitting unit 8 according to the embodiment is only used to increase the light extraction efficiency and the light emission range of the LED die 83. Because the volume and thickness of the molding compound is much smaller than that of the prior art, the wire W connected between the LED die 83 and the substrate 82 can be prevented from deforming or breaking caused by dragging or squeezing. Moreover, after the thickness of the molding compound 85 is decreased, the heat of the LED die 83 can be dissipated from the substrate below and/or from the top of the LED die 83. Additionally, the heat dissipation effect of the LED die 83 can further be enhanced by heat convection effect of the fluid 84 or the gel filled in the chamber C.

The aspects of the molding compound disposition on the LED die can also be used on the light emitting units in various aspects of the above-mentioned embodiment, and some of the aspects are described as follows.

With reference to FIG. 9E, the difference between the light emitting unit 8c and the light emitting unit 8 is that the light emitting unit 8c can further include a reflecting part and at least one fluorescent converting layer 87. The reflecting layer can be a part of the housing 81 or an additional reflecting layer 86 as described in the embodiment.

The reflecting layer 86 is disposed on the outer surface of the housing 81 and has at least one opening 861 corresponding to a light emitting surface of the LED die 83. Furthermore, the reflecting layer 86 may be a reflecting film, a lens, or a multilayer plating material on the outer surface of the housing 8 1.

The wavelength converting material 87 can be disposed on a partial outer surface and/or partial inner surface of at least a part of the housing 81, or doped directly in the housing 81. In the embodiment, the wavelength converting material 87 is disposed on the outer surface of the transparent housing 81 corresponding to the opening 861. The light emitting direction of the light emitting unit 8a can be concentrated by the reflecting layer 86. When there are a plurality of LED dies 83, the light emitted from the LED dies 83 can be mixed in the housing 81 and then emitted out using the reflecting layer 86. Furthermore, the color of the light emitted from the light emitting unit 8c can be changed by the wavelength converting material 87.

In addition, with reference to FIG. 9F, in the light emitting unit 8d, the reflecting layer 86a can be disposed on the inner surface of the housing 81 and the reflecting layer 86a has an opening 861a corresponding to the light emitting surface of the LED die 83. The wavelength converting material 87a may also be disposed on the inner or outer surfaces of the housing 81 corresponding to the opening 861a. Regarding to this, the wavelength converting material 87a is disposed on the inner surface of the housing 81 corresponding to the opening 861a for example. Moreover, with reference to FIG. 9G, the light emitting unit 8e may also allow the reflecting layers 86b and 86c to be disposed on the inner and outer surfaces of the housing 81 at the same time. It is noted that the reflecting layers 86b and 86c on the inner and outer surfaces of the housing 81 are disposed interlacedly.

With reference to FIG. 9H, in the light emitting unit 8f, the wavelength converting material may also be replaced by a phosphor tape T. The phosphor tape T is disposed on the inner surface and/or the outer surface of at least a part of the housing 81. In this case, the phosphor tape T is disposed on the outer surface of the housing 31 by attaching for example. The phosphor tape T has an adhesive layer T1 and a phosphor layer T2 for example. The phosphor is contained in the phosphor layer T2 by evaporating, coating, or doping.

In addition, the reflecting layer may also be disposed on the surface of the substrate. With reference to FIG. 91, in the light emitting unit 8g, a surface of the substrate 82 has an LED die 83 disposed thereon. A reflecting layer 86d is disposed to the peripheries of the LED dies 83 on the substrate 82. Since the light emitted from the LED die 83 to the substrate 82 can be reflected by the reflecting layer 86d, the light utilization rate of the LED die 83 can be increased. If the substrate 82 is a transparent substrate, the reflecting layer 86d can also be disposed on the surface of the substrate 82 that does not face the LED die 83.

With reference to FIG. 9J, the light emitting unit 8h allows a reflecting housing L to be disposed to the periphery of the LED die 83 on the substrate 82, such that the light emitting direction of the LED dies 83 can be reflected and concentrated. With reference to FIG. 9K, in the light emitting unit 8i, a plurality of LED dies 83 are arranged two-dimensionally. The molding compound 89c only covers the upper surfaces of the LED dies 83 and the contact points connecting the LED dies 83 and the wires W.

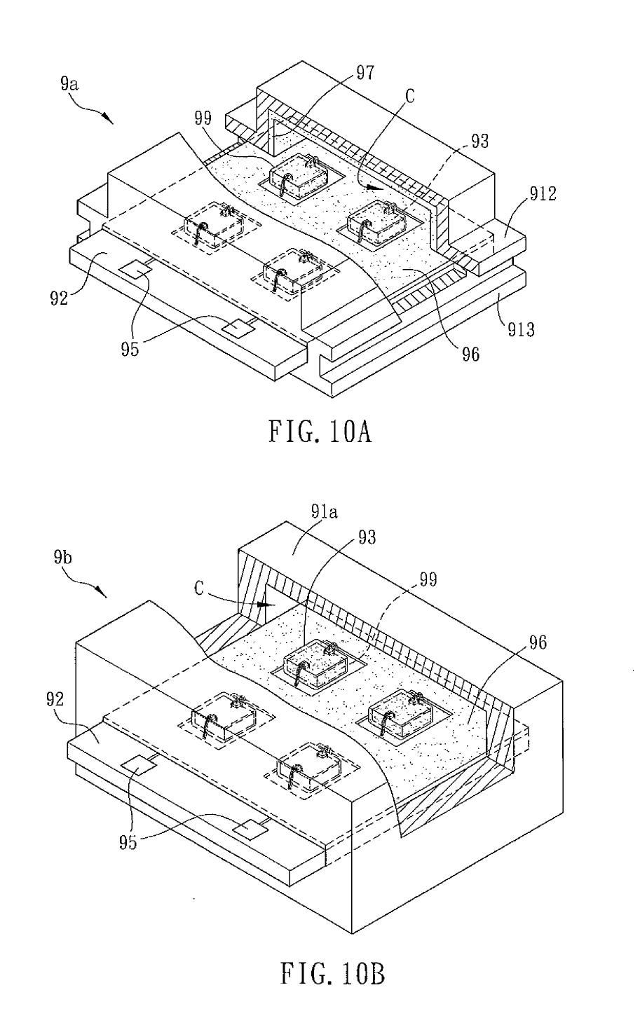

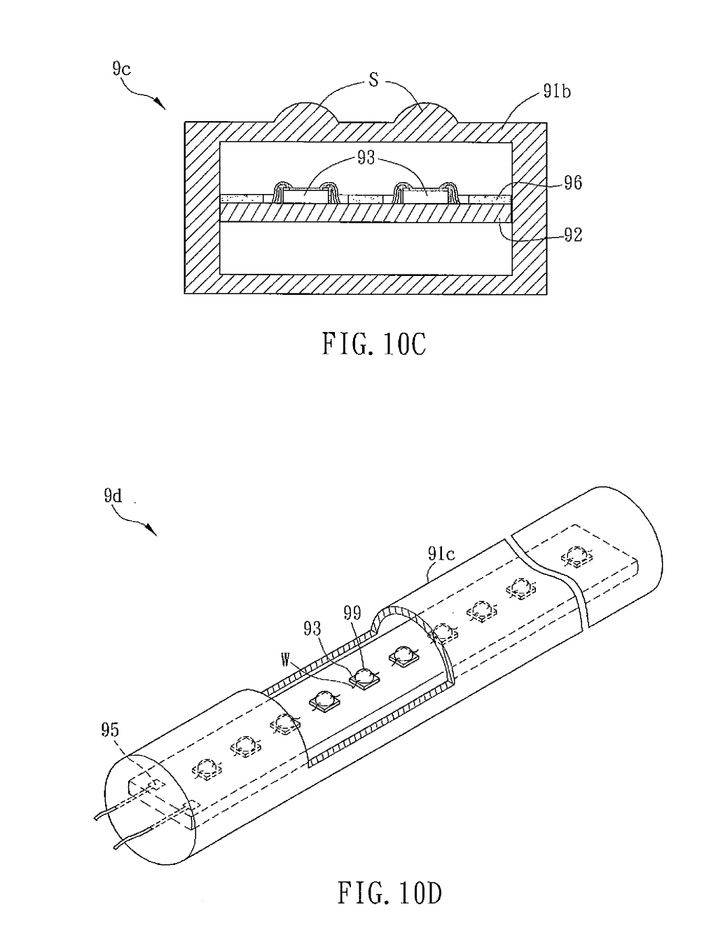

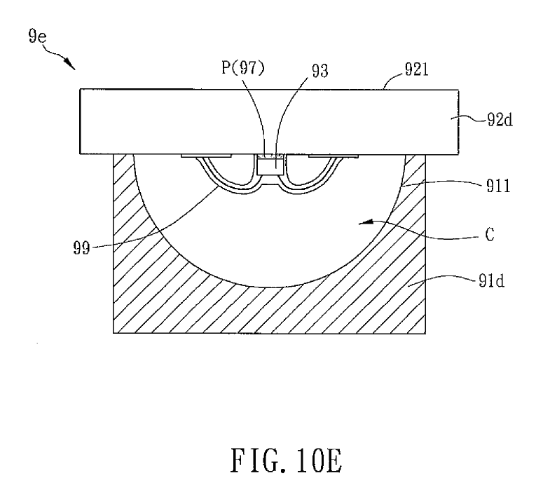

FIGS. 10A to 10E are schematic views of the light emitting unit in different aspects according to the eighth embodiment of the present invention. With reference to FIG. 10A, the chamber C of the light emitting unit 9a are comprised of two housing elements 912 and 913. A plurality of LED dies 93 and at least two connecting electrodes 95 are disposed on the substrate 92. The LED dies 93 are arranged two-dimensionally for example but not limited to this. The substrate 92 is disposed between the two housing elements 912 and 913. A reflecting layer 96 can be disposed or formed on the substrate 92, and a wavelength converting material 97 can be disposed or formed on the housing element 912. Of course, the wavelength converting material 97 can be replaced by the phosphor tape.

With reference to FIG. 10B, the chamber C of the light emitting unit 9b can also be formed by a hollow housing 91a. The hollow housing 91a may also include a reflecting layer 96 and a wavelength converting material disposed on an outer surface and/or an inner surface of a part of the hollow housing 91a. As a matter of course, the wavelength material may also be replaced by the phosphor tape. The cross-sectional shape of the hollow housing 91a may be, for example but not limited to, circle, ellipse, triangle, quadrilateral, polygon, or irregular shape. It may have different various aspects according to different designs, and the hollow housing 91a may have a plurality of scattering centers as described in the previous embodiment.

With reference to FIG. 10G, the difference between the light emitting unit 9c and the light emitting unit 9b is that the light emitting unit 9c may have a lens structure S on the outer surface or the inner surface of the housing 91b corresponding to each LED die 93. Regarding to this, the lens structure S is disposed on the outer surface of the hollow housing 91b for example but not limited to this. By doing so, the light emitted from the LED dies 93 will have a convergence effect.

With reference to FIG. 10D, the chamber C of the light emitting unit 9d is formed by a transparent tube 91c. The molding compound 99 can cover the light emitting surface of the LED die 93 or cover the contact point contacting the LED die 93 and at least one wire W, and the molding compound does not entirely cover the wire W.

With reference to FIG. 10E, the chamber C of the light emitting unit 9e is formed by a housing 91d and a substrate 92d, in which the substrate 91 is a transparent substrate and the housing 91d has a reflecting surface 911. The light emitting unit 9e may further include a die attach adhesive P disposed between the LED die 93 and the substrate 92, so as to surely fix the LED die 93 to the substrate 92. In the embodiment, the wavelength converting material 97 can be doped or mixed in the molding compound 99 and/or the die attach adhesive P. As a matter of course, if the fluorescent conversion effect of the light emitting unit 9e is enhanced, the wavelength converting material 97 can also be disposed on the light emitting surface of the substrate 92d and/or the reflecting surface 911 of the housing 91d. Moreover, the gel or the fluid can be filled in the chamber C again, and doped with the wavelength converting material 97. In the embodiment, a part of the light emitted from the LED die 3 can excite the wavelength converting material 97 in the die attach adhesive P to generate the light with different colors to directly emit out through the substrate 92d. The other part of the light can be reflected by the reflecting surface 911 of the housing 91d and then emitted out through the substrate 92d. Hence the light emitting unit 9e can emit a light with mixed color, such as a white light.

To sum up, in the light emitting unit according to the present invention, the LED die is disposed in a chamber, such that the light emitting unit no longer needs the molding compound with a large area and high thickness to cover the entire LED dies. Without the separation of the molding compound, the heat of the LED die can be dissipated from not only the substrate below but also the top of the LED die. The heat dissipation effect can further be enhanced by heat convection effect of the gel or the fluid. Furthermore, the housing can protect the LED die from the environmental factor such as moister or dust and prevent the wire connected between the LED die and the substrate from deforming and breaking due to squeezing and dragging. Moreover, the light emitting unit of the present invention may also use the molding compound partially covering the single LED die for enhancing the light extraction efficiency and the light emission range of the LED die.

In addition, the light emitting unit can further include a reflecting layer and a wavelength converting material. The housing having a reflecting layer disposed thereon not only can increase the light extraction efficiency in a fixed light emitting direction and also can mix the light from the LED dies in the housing before it is emitted out. The wavelength converting material can be used to change the color of the emitted light to expand the applications of the light emitting unit. The wavelength converting material can further be replaced by the phosphor tape to increase the manufacturing efficiency and the product reliability.

In addition, since there is no circuit layer on the substrate, the substrate can be a metal substrate. If the metal substrate combines with the heat dissipating element, the heat dissipation effect of the light emitting unit can be more effectively enhanced. Moreover, if the substrate is a transparent substrate without the covering of the circuit layer, it can effectively increase the probability that the light emitted from the back of the LED die is reflected in the substrate 22 and then emitted out, so as to increase the light utilization rate of the LED die. Additionally, without the circuit layer, the material cost of the substrate may be reduced and the manufacturing rate may be further increased. The overall material cost can further be reduced by decreasing about half of the amount of the gold wire used for the LED dies

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting unit having a chamber, comprising:
a substrate;
a plurality of light emitting diode (LED) dies disposed on the substrate and located in the chamber; and
a gel or a fluid filled in the chamber.

2 The light emitting unit according to claim 1, where the material of the substrate comprises glass, resin, ceramics, alloy, metal, or their combination.

3. The light emitting unit according to claim 1, further comprising:
a wavelength converting material doped in the substrate, the gel, and/or the fluid.

4. The light emitting unit according to claim 1, wherein the LED dies are respectively connected to the substrate by flip-chip or wire-bonding.

5. The light emitting unit according to claim 1, wherein the LED dies are respectively disposed on the substrate by a die attach adhesive.

6. The light emitting unit according to claim 5, further comprising:
a wavelength converting material mixed in the die attach adhesive or disposed on a side of the die attach adhesive.

7. The light emitting unit according to claim 1, further comprising:
a light scattering element, a light refracting element, or a light reflecting element disposed between two of the LED dies.

8. The light emitting unit according to claim 1, further comprising:
a reflecting layer disposed on the substrate.

9. The light emitting unit according to claim 8, further comprising:
a wavelength converting material disposed on the reflecting layer or a side of the substrate opposite to the reflecting layer.

10. The light emitting unit according to claim 1, further comprising:
a housing combining with the substrate to form the chamber.

11. The light emitting unit according to claim 10, wherein the housing is a transparent housing.

12. The light emitting unit according to claim 10, wherein the housing comprises a plurality of lens structures corresponding to the LED dies, respectively.

13. The light emitting unit according to claim 10, wherein the housing comprises a reflecting surface, and the reflecting surface reflects out at least a part of the light emitted by the LED dies through the substrate.

14. The light emitting unit according to claim 13, wherein the housing comprises a reflecting layer used as the reflecting surface located on an outer surface and/or an inner surface of the housing.

15. The light emitting unit according to claim 13, wherein the reflecting surface is a curved reflecting surface.

16. The light emitting unit according to claim 10, wherein the housing is a metal housing or alloy housing.

17. The light emitting unit according to claim 10, further comprising:
a heat dissipating unit disposed on the housing.

18. The light emitting unit according to claim 10, further comprising:
at least one wavelength converting material disposed on the reflecting surface of the housing and/or a side of the substrate, and/or doped in the housing.

19. The light emitting unit according to claim 1, further comprising:
a transparent tube being at least partially transparent, wherein the chamber is located in the transparent tube and the substrate is disposed in the chamber.

20. The light emitting unit according to claim 19, wherein the transparent tube comprises a reflecting part.

21. The light emitting unit according to claim 19, further comprising:
a reflecting layer disposed on an outer surface and/or an inner surface of a part of the transparent tube.

22. The light emitting unit according to claim 19, wherein the transparent tube comprises at least two housing elements, and the housing elements are connected to each other to form the transparent tube.

23. The light emitting unit according to claim 19, further comprising:
at least one wavelength converting material disposed on an outer surface and/or inner surface of at least a part of the transparent tube, and/or doped in the transparent tube.

24. The light emitting unit according to claim 19, further comprising:
two connecting electrodes electrically connected to the exterior of the transparent tube.

25. The light emitting unit according to claim 24, wherein the connecting electrodes are disposed on an end of the substrate or respectively on two ends of the substrate.

26. The light emitting unit according to claim 1, further comprising:
at least two housing elements having the chamber formed therebetween.

27. The light emitting unit according to claim 26, wherein at least one of the housing elements comprises a reflecting part.

28. The light emitting unit according to claim 26, further comprising:
a reflecting layer disposed on a partial outer surface and/or a partial inner surface of at least one of the housing elements.

29. The light emitting unit according to claim 26, further comprising:
at least one wavelength converting material disposed on a partial outer surface and/or a partial inner surface of at least one of the housing elements, and/or doped in the housing elements.

30. The light emitting unit according to claim 1, further comprising:
a hollow housing having the chamber located therein.

31. The light emitting unit according to claim 30, wherein the hollow housing comprises a plurality of lens structures corresponding to the LED dies, respectively.

32. The light emitting unit according to claim 30, wherein the hollow housing comprises a reflecting part.

33. The light emitting unit according to claim 30, her comprising:
a reflecting layer disposed on an outer surface and/or an inner surface of a part of the hollow housing.

34. The light emitting unit according to claim 30, further comprising:
at least one wavelength converting material disposed on at least a partial outer surface and/or at least a partial inner surface of the hollow housing, and/or doped in the hollow housing.

35. The light emitting unit according to claim 1, further comprising:
at least one molding compound covering at least a part of one of the LED dies.

36. The light emitting unit according to claim 35, further comprising:
at least one wire having a first end connected to the LED die and a second end connected to the substrate, wherein a first distance is formed between the second end and the center point of the LED die, a second distance is formed between the highest point of the wire and the substrate, the total volume of the molding compound and the LED die is smaller than the volume of a cylinder formed by the first distance and the second distance, and the first distance is the radius of the cylinder.

37. The light emitting unit according to claim 35, wherein at least a part of the wire is exposed from the molding compound.

38. The light emitting unit according to claim 1, wherein at least two of the LED dies are electrically connected in series or in parallel by die-to-die wire-bonding.

39. The light emitting unit according to claim 1, further comprising:
a control chip disposed on the substrate and controlling the LED dies.

40. The light emitting unit according to claim 1, further comprising:
a flexible circuit board connected to an end of the substrate and exposed from the chamber.
